(19) United States
(12) Patent Application Publication
(10) Pub. No.: US 2026/0164900 A1
(43) Pub. Date: Jun. 11, 2026

(54) Stamp Element for Transferring Light Emitting Diode and Black Matrix Pattern of Display Device

(71) Applicant: LG Display Co., Ltd., Seoul (KR)

(72) Inventors: Jae-Hoon Jang, Paju-si (KR); Joon-Kwon Moon, Paju-si (KR); Chan Kim, Paju-si (KR); Jae-Kyung Shin, Paju-si (KR)

(21) Appl. No.: 19/294,698

(22) Filed: Aug. 8, 2025

(30) Foreign Application Priority Data
Dec. 11, 2024 (KR) 10-2024-0183941

(51) Int. Cl. H10H 29/855; H01L 21/67; H10H 29/03

(52) U.S. Cl. CPC H10H 29/8552; H10H 29/03; H10P 72/0438

(57) ABSTRACT

A stamp element for transferring a light emitting diode and a black matrix pattern of a display device are disclosed. A stamp element for transferring a light emitting diode in some examples can include a plurality of detachment components with different separation distances by areas. A black matrix pattern of a display device in some examples can include a plurality of light blocking patterns with different line widths by area. The luminance differences of light emitted from the light emitting diode at a boundary region can be minimized, and the image quality of the display device can be improved by applying the stamp element and/or the black matrix pattern.

### CROSS-REFERENCE TO RELATED APPLICATION

This application claims priority under 35 U.S.C. § 119(a) to the Republic of Korea Patent Application No. 10-2024-0183941, filed on Dec. 11, 2024, which is hereby incorporated by reference in its entirety.

### TECHNICAL FIELD

The present disclosure relates to an apparatus and particularly to, for example, without limitation, a stamp element and a black matrix pattern, and more particularly to, a stamp element for transferring a light emitting diode and a black matrix pattern structure that can minimize luminance differences by areas.

### DISCUSSION OF THE RELATED ART

As large display devices have been developed, a need for flat display devices with small occupations has increased. Particularly, technologies for a light emitting display device including a light emitting diode as the flat display devices have rapidly developed. The light emitting display device can be classified as an organic light emitting display device using organic luminous materials and an inorganic light emitting display device using inorganic luminous materials.

The organic light emitting display device has an advantage of not requiring a separate light source. However, the organic light emitting display device has a disadvantage in that effects are likely to occur caused by external environment due to the material properties of organic materials vulnerable to moisture and oxygen.

In order to solve that disadvantages, a display device using a light emitting diode chip (or light emitting diode) into which inorganic luminous materials are applied. Such light emitting diode chip can be picked up on a growth substrate and then attached to a display panel through a transfer process suing a stamp.

### SUMMARY

The inventors of the present disclosure have recognized that when the light emitting diode chips are transferred, a stamp mura or stains can occur due to the wavelength distributions within the growth substrate. In addition, the arrangements of the light emitting diode chips can be tilted or staggered by the stamp area in the transfer process. As the luminance of light emitted from the light emitting diode chip differentiates by stamp area, the resulting stamp mura can deteriorate image quality.

Accordingly, one or more embodiments of the present disclosure are directed to a stamp element for transferring light emitting diode and/or a black matrix pattern that substantially obviate one or more of the problems due to the limitations and disadvantages of the related art.

An embodiment of the present disclosure is to provide a stamp element for transferring a light emitting diode and/or a black matrix pattern structure that can minimize or at least reduce stains in a stamp boundary region where a transfer process is performed.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a stamp element for transferring a light emitting diode, the stamp element comprises a transfer head; and a plurality of detachment components disposed to protrude from a surface of the transfer head, wherein the plurality of detachment components comprises a plurality of a first detachment components disposed in a central area of the transfer head; and a plurality of peripheral detachment components disposed in a peripheral area of the transfer head, the plurality of first detachment components are disposed with a first separation distance, and at least portions of the plurality peripheral detachment components are disposed with a separation distance different from the first separation distance.

The at least portions of the plurality of peripheral detachment components can comprise a plurality of second detachment components disposed with a second separation distance different from the first separation distance; and a plurality of third detachment components disposed with a third separation distance different from the first separation distance and the second separation distance.

For example, the first separation distance can be greater than the first separation distance and/or the third separation distance can be greater than the second separation distance.

The peripheral area of the transfer head can comprise a first peripheral area between the central area of the transfer head and an edge of the transfer head; and a second peripheral area between the first peripheral area of the transfer head and the edge of the transfer head.

In one embodiment, at least portions of the plurality of peripheral detachment components disposed in the first peripheral area can comprise a plurality of second detachment components disposed with a second separation distance different from the first separation distance, and at least portions of the plurality of peripheral detachment components disposed in the second peripheral area can comprise a plurality of third detachment components disposed with a third separation distance different from the first separation distance and the second separation distance.

In another embodiment, a ratio of the peripheral detachment components with a separation distance different from the first separation distance among the plurality of peripheral detachment components disposed in the first peripheral area can differ from a ratio of the peripheral detachment components with a separation distance different from the first separation distance among the plurality of peripheral detachment components disposed in the second peripheral area.

In another embodiment, at least portions of the plurality of peripheral detachment components disposed in the first peripheral area and the second peripheral area can comprise a plurality of second detachment components disposed with a second separation distance different from the first separation distance, and a ratio of the plurality of second detachment components with the second separation distance among the plurality of peripheral detachment components disposed in the first peripheral area can differ from a ratio of second detachment components with the second separation distance among the plurality of peripheral detachment components disposed in the second peripheral area.

In another embodiment, at least portions of the plurality of peripheral detachment components can be disposed with a second separation distance different from the first separation distance, and a difference between the first separation distance and the second separation distance gradually increases or decreases as a distance from the central area of the transfer head increases.

In another embodiment, a ratio of the peripheral detachment components with a separation distance different from the first separation distance among the plurality of peripheral detachment components can gradually increase as a distance from the central area of the transfer head increases.

In another embodiment, the present disclosure provides a black matrix pattern for a display device, the black matrix pattern comprises a plurality of openings disposed correspondingly to each of emission areas of a display device; and a plurality of light blocking patterns enclosing the plurality of openings, respectively, and disposed correspondingly to each of non-emission areas of the display device, wherein the plurality of light blocking patterns comprise a plurality of first light blocking patterns disposed to enclose the plurality of openings positioned in a first area, respectively; and a plurality of second area light blocking patterns disposed to enclose the plurality of openings positioned in a second area enclosing the first area, respectively, the plurality of first light blocking patterns are disposed with a first line width to each of the plurality of openings, and at least portions of the plurality of second area blocking patterns are disposed with a line width different from the first line width.

The at least portions of the second area light shield patterns can comprise a plurality of second light blocking patterns disposed with a second line width different from the first line width; and a plurality of third light blocking patterns disposed with a third line width different from the first line width and the second line width.

For example, the second line width can be greater than the first line width and/or the third line width can be greater than the first line width.

The second area can comprise a first adjacent area enclosing the first area; and a second adjacent area enclosing the first adjacent area.

In one embodiment, the least portions of the plurality of second area light blocking patterns disposed in the first adjacent area can comprise a plurality of second light blocking patters with a second line width different from the first line width, and at least portions of the plurality of second area light blocking patterns disposed in the second adjacent area can comprise a plurality of third light blocking patterns with a third line width different from the first line width and the second line width.

In another embodiment, a ratio of the second area light blocking patterns with a line width different from the first line width among the plurality of second area light blocking patterns disposed in the first adjacent area can differ from a ratio of the second area light blocking patterns with the line width different from the first line width among the plurality of second area light blocking patterns disposed in the second adjacent area.

In another embodiment, the at least portions of the plurality of second area light blocking patterns disposed in the first adjacent area and the second adjacent area can comprise a plurality of second light blocking patterns disposed with a second line width different from the first line width, and a ratio of the second light blocking patterns with the second line width among the plurality of second area light blocking patterns disposed in the first adjacent area can differ from a ratio of the second light blocking patterns with the second line width among the plurality of second area light blocking patterns disposed in the second adjacent area.

In another embodiment, at least portions of the plurality of second area light blocking patterns can be disposed with a second line width different from the first line width, and a difference between the first line width and the second line width can gradually increases or decreases as a distance from the first area increases.

In another embodiment, a ratio of the second area light blocking patterns with a line width different from the first line width among the plurality of second area light blocking patterns can gradually increase as a distance from the first area increases.

In one or more embodiments, the stamp element for transferring a light emitting diode can comprise the plurality of detachment components with different separation distances by areas of the transfer head, and the black matrix pattern can comprise the plurality of light blocking patterns with different line widths by areas.

The separation distances between at least portions of the plurality detachment components can be designed differently and/or the ratio of the detachment components with different separation distance can be designed differently by the stamp areas. In addition, the line widths among the light blocking patterns disposed between the opening and/or the ratio of the light blocking patterns with different line width can be designed differently by the area.

The selected light diode using the stamp element with different separation distances among the detachment components can be transferred to the display panel and/or the black matrix using the black matrix pattern with different line widths can be arranged to a non-emission area of the display panel.

The stains at the boundary region in the display panel into which the light emitting diode is transferred and/or in the display panel into which the black matrix is arranged can be minimized. The luminance of light emitted from the light emitting diode in the stamp boundary region or other boundary region can be minimized, and the display device with beneficial image quality can be implemented by applying the stamp element and/or the black matrix pattern into the display panel.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic function block diagram of a display device that can be fabricated by a stamp element and/or a black matrix pattern in accordance with one or more embodiments of the present disclosure.

FIG. 2 illustrates a schematic circuit diagram of a display device that can be fabricated by a stamp element and/or a black matrix pattern in accordance with one or more embodiments of the present disclosure.

FIG. 3 illustrates a schematic sub-pixel structure in a display panel of the display device that can be fabricated by the stamp element and/or the black matrix pattern in accordance with one or more embodiments of the present disclosure.

FIG. 4 illustrates a schematic stamp area where a transfer process to the display panel is performed in accordance with one or more embodiments of the present disclosure.

FIG. 5 illustrates a schematic diagram illustrating a difference in luminance of light emitted from the light emitting diode by the stamp area caused by the alignment of the light emitting diode is misaligned by the stamp area when transferring the light emitting diode using a conventional stamp element.

FIG. 6 is a photograph showing a mura or a stain in the boundary area among the stamp areas when the light emitting diodes are transferred using the conventional stamp element.

FIG. 7 illustrates a schematic light emitting diode transfer apparatus including a stamp element in accordance with one or more embodiments of the present disclosure.

FIG. 8 illustrates a schematic of a configuration of a transfer head and one detachment component in the stamp element in accordance with one or more embodiments of the present disclosure.

FIG. 9 illustrates a schematic arrangement of plural detachment components disposed on one surface of the transfer head in the stamp element in accordance with one or more embodiments of the present disclosure.

FIG. 10 illustrates a schematic arrangement of plural detachment components disposed in a central area of the transfer head in the stamp element in accordance with one or more embodiments of the present disclosure.

FIGS. 11A and 11B illustrate a schematic arrangement of plural detachment components in a peripheral area of the transfer head in the stamp element in accordance with one embodiment of the present disclosure.

FIG. 12 illustrates a schematic arrangement of plural detachment components in the peripheral area of the transfer head in the stamp element in accordance with other embodiments of the present disclosure.

FIG. 13 illustrates a schematic arrangement of plural detachment components in the peripheral area of the transfer head in the stamp element in accordance with another embodiment of the present disclosure.

FIG. 14 illustrates a schematic arrangement of plural detachment components in the peripheral area of the transfer head in the stamp element in accordance with another embodiment of the present disclosure.

FIG. 15 illustrates a schematic arrangement of plural detachment components in the peripheral area of the transfer head in the stamp element in accordance with another embodiment of the present disclosure.

FIG. 16 illustrates a schematic arrangement of plural detachment components in the peripheral area of the transfer head in the stamp element in accordance with another embodiment of the present disclosure.

FIG. 17 illustrates a schematic diagram illustrating an alignment of the light emitting diode chip matches in the boundary area of stamp areas when the light emitting diode is transferred to the display panel using the stamp element in accordance with one or more embodiments of the present disclosure.

FIG. 18 illustrates a schematic diagram illustrating a mura or a stain is hardly visible by the match of light luminance in the boundary area of the stamp area when the light emitting diode is transferred to the display panel using the stamp element in accordance with one or more embodiments of the present disclosure.

FIG. 19 illustrates a schematic arrangement of black matrix patterns in accordance with one or more embodiments of the present disclosure.

FIG. 20 illustrates a schematic arrangement of black matrix patterns in a first area in accordance with one or more embodiments of the present disclosure.

FIGS. 21A and 21B illustrate a schematic arrangement of black matrix patterns in a second area in accordance with one embodiment of the present disclosure.

FIG. 22 illustrates a schematic arrangement of black matrix patterns in a first adjacent area in accordance with one or embodiments of the present disclosure.

FIG. 23 illustrates a schematic arrangement of black matrix patterns in a second adjacent area in accordance with another embodiment of the present disclosure.

FIG. 24 illustrates a schematic arrangement of black matrix patterns in a second adjacent area in accordance with another embodiment of the present disclosure.

FIG. 25 illustrates a schematic arrangement of black matrix patterns in a second adjacent area in accordance with another embodiment of the present disclosure.

FIG. 26 illustrates a schematic arrangement of black matrix patterns in a second adjacent area in accordance with another embodiment of the present disclosure.

FIG. 27 illustrates a schematic diagram illustrating an alignment of the light emitting diode chip matches in the boundary area of stamp areas when the light emitting diode is transferred to the display panel using the black matrix pattern in accordance with one or more embodiments of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the other component is directly on the other component or layer, or where there is a third layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompasses all the meanings and coverages of the term “may” and vice versa.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical idea of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

Any implementation described herein as an “example” is not necessarily to be construed as preferred or advantageous over other implementations.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

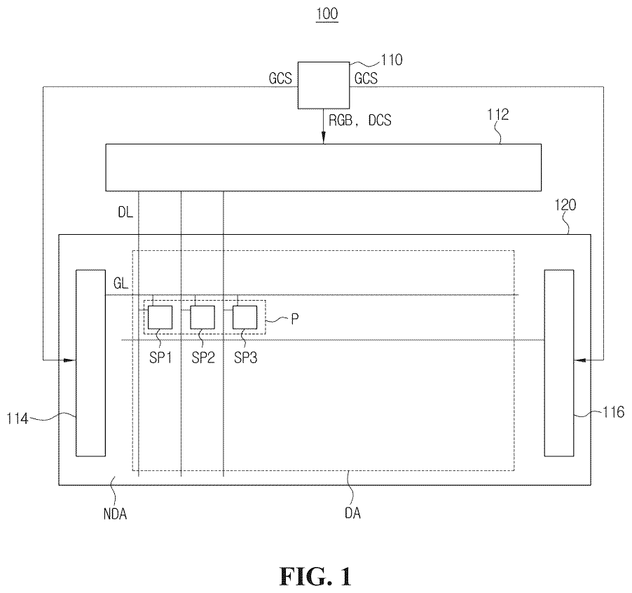

FIG. 1 illustrates a schematic function block diagram of a display device that can be fabricated by a stamp element and/or a black matrix pattern in accordance with one or more embodiments of the present disclosure. The display device can comprise a light emitting diode display device, but is not limited thereto. For example, the display device can be a micro light emitting diode display device, a mini light emitting diode display device or a nano light emitting diode display device.

Referring to FIG. 1, a light emitting display device comprises a timing controller 110, a data driver 112, and first and second gate drivers 114 and 116, and a display panel 120.

The timing controller 110 can generate an image data RGB, a data control signal DCS and a gate control signal GCS using various timing signals such as an image signal, a data enable signal, a horizontal synchronization signal, a vertical synchronization signal, a clock, and the like transferred from an external system such as a graphic card and TV system. The timing controller 110 transfers the generated image data RGB and the data control signal DCS to the data driver 112 and transfers the generated gate control signal GCS to the first and second gate drivers 114 and 116.

The data driver 112 generates a data signal or data voltage using the image data RGB and the data control signal DCS transferred from the timing controller 110 and applies the generated data signal to a data line DL of the display panel 120.

The first and second gate drivers 114 and 116 generate a gate signal or gate voltage using the gate control signal GCS transferred from the timing controller 110 and applies the generated gate signal to a gate line GL of the display panel 120.

For example, the first and second gate drivers 114 and 116 can be configured together in a substrate of the display panel 120 in which the gate line GL, the data line DL and a pixel P are formed and disposed in a non-display area NDA to form a gate in panel (GIP) type.

In FIG. 1, the first and second gate drivers 114 and 116 are disposed in both sides of the display panel 120. In another embodiment, one gate driver can be disposed in one side of the display panel 120.

The display panel 120 comprises a central display area DA and a non-display area NDA enclosing or surrounding the display area DA and displays an image using the gate single and the data signal. The display panel 120 comprises plural pixel P, plural gate lines GLs and plural data lines DLs disposed in the display area DA for displaying images.

Each of plural pixels Ps includes a first to third sub-pixels SP1, SP2 and SP3, and the gate line GL and the data line DL crosses each other to define the first to third sub-pixels SP1, SP2 and SP3. Each of the first to third sub-pixels SP1, SP2 and SP3 is connected to the gate line GL and the data line DL. For example, the first to third sub-pixels SP1, SP2 and SP3 correspond to a first to third colors, respectively, and the first to third colors can be red, green and blue, respectively.

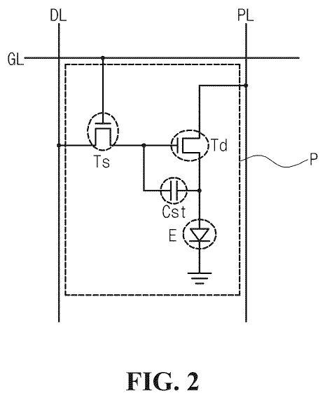

Each of the first to third sub-pixels SP1, SP2 and SP3 can comprise multiple transistors such as a switching thin film transistor Ts (FIG. 2) and a driving thin film transistor Td (FIG. 2), a storage capacitor Cst (FIG. 2), and a light emitting diode E (FIG. 2).

FIG. 2 illustrates a schematic circuit diagram of a display device that can be fabricated by a stamp element and/or a black matrix pattern in accordance with one or more embodiments of the present disclosure.

Referring to FIGS. 1 and 2, the gate line GL, the data line DL and a power line PL crossing each other to defined the pixel P are disposed in the display device 100. The switching thin film transistor Ts, the driving thin film transistor Td, the storage capacitor Cst and the light emitting diode E are configured in the pixel P.

The switching thin film transistor Ts is connected to the gate line GL and the data line DL, and the driving thin film transistor Td and the storage capacitor Cst are connected between the switching thin film transistor Ts and the power line PL. The light emitting diode E is connected to the driving thin film transistor Td. In the light emitting display device 100, when the switching thin film transistor Ts is turned on by the gate signal applied to the gate line GL, the data signal applied to the data line DL is applied to a gate electrode of the thin film transistor Td and one electrode of the storage capacitor Cst through the switching thin film transistor Ts.

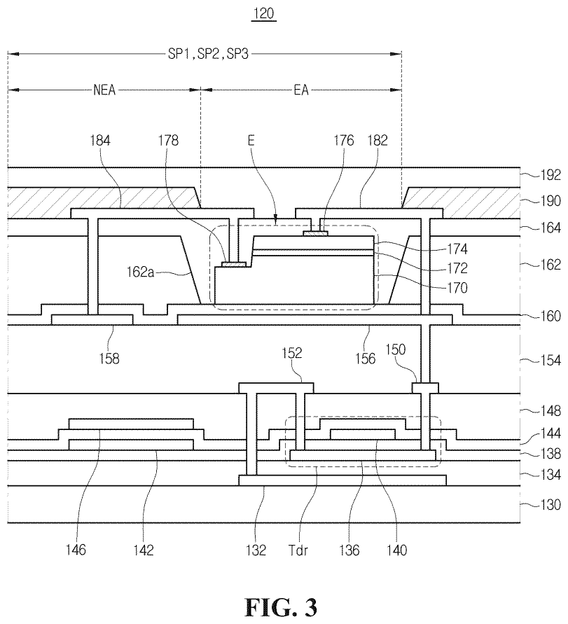

The driving thin film transistor Td is turned on by the data signal applied to a gate electrode 140 (FIG. 3). As a result, current proportional to the data signal flows to the light emitting diode E from the power line PL through the driving thin film transistor Td, and the light emitting diode E emits with luminance proportional to the current flowing through the driving thin film transistor Td. In this case, the storage capacitor Cst is charged with voltages proportional to the data signal and voltages of the gate electrode in the driving thin film transistor Td is kept constantly during one framed. Therefore, the light emitting display device 100 can display desired images.

FIG. 3 illustrates a schematic sub-pixel structure in a display panel of the display device that can be fabricated by the stamp element and/or the black matrix pattern in accordance with one or more embodiments of the present disclosure. As used herein, the term “micro light emitting diode (micro LED)” is intended to includes a nano light emitting diode (nano LED) and a mini light emitting diode (mini LED).

Referring to FIG. 3, each of the first to third sub-pixel SP1, SP2 and SP3 of the display panel 120 can comprise a substrate 130 including an emission area EA and a non-emission area NEA, a light emitting diode E disposed correspondingly to the emission area EA on the substrate 130, and a black matrix 190 disposed correspondingly to the non-emission area NEA on the substrate 130.

The substrate 130 can comprise a transparent material. In one embodiment, the substrate 130 can be a glass substrate, a thin flexible substrate or a polymer plastic substrate. For example, the flexible substrate can comprise, but is not limited to, polyimide (PI), polyether sulfone (PES), polyethylene naphthalate (PEN), polyethylene terephthalate (PET) and/or polycarbonate (PC).

A light shielding pattern 132 is disposed on the substrate 130 and a first buffer layer 134 is disposed on the light shielding pattern 132 covering the entire substrate 130.

The light shielding pattern 132 serves to block light incident from the lower portion of the substrate 130. For example, the light shielding pattern 132 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The light shielding pattern 132 can have a single-layer structure of a multi-layer structure.

The first buffer layer 134 serves to block moisture or oxygen penetrating from the outside. For example, the first buffer layer 134 can comprise, but is not limited to, an inorganic insulating material such as silicon oxide (SiOₓ) and silicon nitride (SiNₓ) (wherein 0<x≤2). The first buffer layer 134 can have a single-layer structure of a multi-layer structure.

A semiconductor layer 136 is disposed on the first buffer layer 134 corresponding to the light shielding pattern 132 and a gate insulating layer 138 is disposed on the semiconductor layer 136 covering the entire substrate 130.

The semiconductor layer 136 can include a central channel area not doped with impurities, and a source area and a drain area doped with impurities at both sides of the channel area. For example, the semiconductor layer 136 can comprise, but is not limited to, a polycrystalline semiconductor material such as polycrystalline silicon and/or an oxide semiconductor material such as indium-gallium-zinc oxide (IGZO), zinc oxide (ZnO), tin oxide (SnO₂), copper oxide (Cu₂O), nickel oxide (NiO), indium-tin-zinc oxide (ITZO) and indium aluminum zinc oxide (IAZO).

For example, the gate insulating layer 138 can comprise, but is not limited to, an inorganic insulating material such as silicon oxide (SiOₓ) and silicon nitride (SiNₓ) (wherein 0<x≤2). The gate insulating layer 138 can have a single-layer structure of a multi-layer structure. In FIG. 3, the gate insulating layer 138 is disposed on the entire substrate 130. In another embodiment, the gate insulating layer 138 can be patterned as the gate electrode 140.

The gate electrode 140 is disposed on the gate insulating layer 138 corresponding to the channel area of the semiconductor layer 136 and a first capacitor electrode 142 spaced apart from the gate electrode 140 is disposed on the gate insulating layer 138. A first interlayer insulating layer 144 is disposed on the gate electrode 140 and the first capacitor electrode 142 covering the entire substrate 130.

The gate electrode 140 and the first capacitor electrode 142 can be disposed with the same layer and same material. For example, the gate electrode 140 and the first capacitor electrode 142 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The gate electrode 140 and the first capacitor electrode 142 can have a single-layer structure of a multi-layer structure.

For example, the first interlayer insulating layer 144 can comprise, but is not limited to, an inorganic insulating material such as silicon oxide (SiOₓ) and silicon nitride (SiNₓ) (wherein 0<x≤2). The first interlayer insulating layer 144 can have a single-layer structure of a multi-layer structure.

A second capacitor electrode 146 is disposed on the first interlayer insulating layer 144 corresponding to the first capacitor electrode 142, and a second interlayer insulating layer 148 is disposed on the second capacitor electrode 146 covering the entire substrate 130.

For example, the second capacitor electrode 146 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The second capacitor electrode 146 can have a single-layer structure of a multi-layer structure.

For example, the second interlayer insulating layer 148 can comprise, but is not limited to, an inorganic insulating material such as silicon oxide (SiOₓ) and silicon nitride (SiNₓ) (wherein 0<x≤2). The second interlayer insulating layer 148 can have a single-layer structure of a multi-layer structure.

The first capacitor electrode 142, the first interlayer insulating layer 144 and the second capacitor electrode 146 can constitute the storage capacitor Cst (FIG. 2)

A source electrode 150 and a drain electrode 152 spaced apart from each other are disposed on the second interlayer insulating layer 148.

The source electrode 150 and the drain electrode 152 is connected to the source area and the drain area of the semiconductor layer 136, respectively, through a contact hole in the second interlayer insulating layer 148, the first interlayer insulating layer 144 and the gate insulating layer 138. In addition, the drain electrode 152 can be connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 can be disposed with the same layer and same material. For example, the source electrode 150 and the drain electrode 152 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The source electrode 150 and the drain electrode 152 can have a single-layer structure of a multi-layer structure.

The semiconductor layer 136, the gate electrode 140, the source electrode 150 and the drain electrode 152 constitute the thin film transistor Tdr acting as a driving element. In FIG. 3, the thin film transistor Tdr has a coplanar structure where the gate electrode 140, the source electrode 150 and the drain electrode 152 are positioned on the semiconductor layer 136. In another embodiment, the thin film transistor Tdr has an inverted staggered structure where a gate electrode is positioned under a semiconductor layer and a source electrode and a drain electrode are positioned on the semiconductor layer. In this case, the semiconductor layer can comprise amorphous silicon.

A first planarization layer 154 is disposed on the source electrode 150 and the drain electrode 152 covering the entire substrate 130. For example, the first planarization layer 154 can comprise, but is not limited to, an organic insulating material such as photo-acryl and/or benzocyclobutene (BCB). The first planarization layer 154 can have a single-layer structure or a multi-layer structure.

A connection electrode 150 is disposed on the first planarization layer 154 corresponding to the source electrode 150, and a power line 158 spaced apart from the connection electrode 156 is disposed on the first planarization layer 154. The connection electrode 156 is connected to the source electrode 150 through a contact hole in the first planarization layer 154. The connection electrode 156 and the power line 158 can be disposed with the same layer and same material.

For example, the connection electrode 156 and the power line 158 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The connection electrode 156 and the power line 158 can have a single-layer structure of a multi-layer structure. As an example, the power line 158 can provide a low-potential signal.

A first passivation layer 160 can be disposed on the connection electrode 156 and the power line 158 covering the entire substrate 130. For example, the first passivation layer 160 can comprise, but is not limited to, an inorganic insulating material such as silicon oxide (SiOₓ) and silicon nitride (SiNₓ) (wherein 0<x≤2). The first passivation layer 160 can have a single-layer structure of a multi-layer structure. Alternatively or additionally, an adhesive layer can be further disposed on the connection electrode 150 and the power line 158 covering the entire substrate 130.

A second planarization layer 162 is disposed on the first passivation layer 160 covering the entire substrate 130 and the light emitting diode E is disposed on an opening 162a that is formed by removing a portion of the second planarization layer 162. As an example, a first semiconductor layer 170 is disposed on the opening 162a of the second passivation layer 162 on the first passivation layer 160 corresponding to the connection electrode 156. An active layer 172, a second semiconductor layer 174 and a first electrode 176 are disposed sequentially on an upper portion of the first semiconductor layer 170, and a second electrode 178 is disposed on another upper portion of the first semiconductor layer 170. Alternatively or additionally, the light emitting diode E can further comprise a non-doped gallium nitride layer disposed under the first semiconductor layer 170 and an ohmic contact layer having a transparent conductive material disposed on the second semiconductor layer 174.

The first semiconductor layer 170 provides electrons to the active layer 172 and the second semiconductor layer 174 provides holes to the active layer 172. The active layer 172 generates light using electrons and holes.

For example, the first semiconductor layer 170 can be an n-type gallium nitride (n-GaN) layer including gallium nitride (GaN) and an n-type impurity such as Si, Ge, Se, Te and/or carbon (C), and the second semiconductor layer 174 can be a p-type gallium nitride (p-GaN) layer including gallium nitride (GaN) and a p-type impurity such as Mg, Zn and/or Ba, but is not limited thereto.

The active layer 172 can comprise a multi quantum well (MQW). For example, a plurality of barrier layers and well layers are alternately arranged in the MQW structure in the active layer 172. The well layer can comprise InGaN and the barrier layer can comprise GaN, but is not limited thereto.

For example, the first electrode 176 can be an anode and the second electrode 178 can be a cathode. For example, the first electrode 176 and the second electrode 178 can comprise, but is not limited to, a metal component such as molybdenum (Mo), aluminum (Al), chrome (Cr), gold (Au), titanium (Ti), nickel (Ni), neodymium (Nd), copper (Cu) and/or alloys thereof. The first electrode 176 and the second electrode 178 can have a single-layer structure of a multi-layer structure.

The first semiconductor layer 170, the active layer 172, the second semiconductor layer 174, the first electrode 176 and the second electrode 178 can constitute the light emitting diode E (or a light emitting diode chip). The wavelength of the light emitted from the light emitting diode E can be controlled by a thickness of the barrier layer in the MQW structure of the active layer 172. As an example, the light emitting diode E can have a thickness, but is not limited to, about 10 μm to about 100 μm.

In FIG. 3, while the light emitting diode E is disposed on the first passivation layer 160, but the present disclosure is not limited to the particular light emitting diode E. The light emitting diode E can comprise a light emitting diode having various structures such as a vertical structure light emitting diode and/or a horizontal structure light emitting diode.

A third planarization layer 164 is disposed on the first and second electrode 176 and 178 covering the entire substrate 130, and first and second connection lines 182 and 184 spaced apart from each other are disposed on the third planarization layer 164 corresponding to the light emitting diode E.

For example, the second planarization layer 162 and the third planarization layer 164 can comprise, but is not limited to, an organic insulating material such as photo-acryl and/or benzocyclobutene. The second planarization layer 162 and the third planarization layer 164 can have a single-layer structure or a multi-layer structure.

The first connection line 182 is connected to the connection electrode 156 through a contact hole in the first passivation layer 160, the second planarization layer 162 and the third planarization layer 164, and the to the first electrode 176 through a contact hole in the third planarization layer 164.

The second connection line 184 is connected to the power line 158 through a contact hole in the first passivation layer 160, the second planarization layer 162 and the third planarization layer 164, and the to the second electrode 178 through a contact hole in the second planarization layer 162 and the third planarization layer 164.

For example, each of the first and second connection lines 182 and 184 can comprise, but is not limited to, a transparent conductive material such as indium-tin oxide (ITO), indium-zinc oxide (IZO), indium-tin-zinc oxide (ITZO) and indium-gallium-zinc oxide (IGZO).

A black matrix 190 can be disposed on the third planarization layer 164. The black matrix 190 can be disposed on the third planarization layer 164 correspondingly to the non-emission area NEA in each of the sub-pixels SP1, SP2 and SP3. The black matrix 190 can prevent or reduce light mixing between the plural sub-pixels SP1, SP2 and SP3. The black matrix 190 can comprise a light-blocking or light-absorbing material. For example, the black matrix 190 can comprise a black colorant, but is not limited thereto. The black matrix 190 can be disposed on the third planarization layer 164 with a patterned shape by coating a compositing including the black colorant and a photosensitive resin on the third planarization layer 164 and then performing a photolithography process.

A color conversion layer can be disposed on the third planarization layer 164. The color conversion layer can be disposed on the light emitting diode E that is positioned correspondingly to the emission area EA on the substrate 130. The color conversion layer can comprise, but is not limited to, quantum dots and/or a fluorescent material.

A second passivation layer 192 is disposed on the first and second connection lines 182 and 184 and the black matrix 190 covering the entire substrate 130. The second passivation layer 192 suppresses the penetration of impurities such as oxygen and/or moisture. For example, the second passivation layer 192 can comprise, but is not limited to, an inorganic insulating material such as silicon oxide (SiOₓ) and silicon nitride (SiNₓ) (wherein 0<x≤2). The second passivation layer 192 can have a single-layer structure of a multi-layer structure.

The light emitting diode E (or the light emitting diode chip) can be transferred to the display panel 120 and be applied to the light emitting display device 100. When the light emitting diode E is transferred to the display panel 120 from the growth substrate or the generation substrate, a transfer process using a stamp element or a stamp member can be performed.

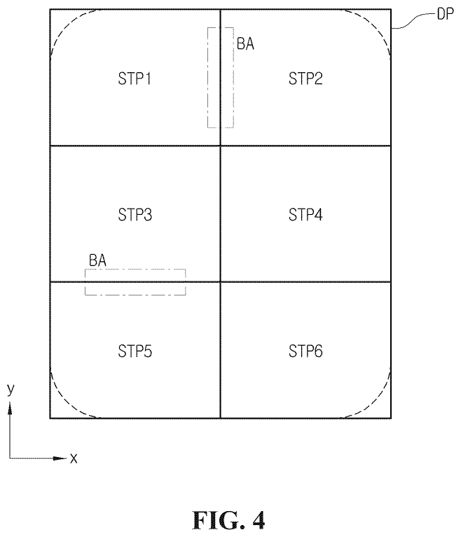

Since a size of the stamp element is limited, it is difficult to simultaneously transfer multiple light emitting diodes to a large-area display panel using one stamp element. Therefore, multiple light emitting diodes are transferred to the display panel DP using a plurality of stamp elements having a plurality of stamp areas STP1 to STP6 (FIG. 4), respectively.

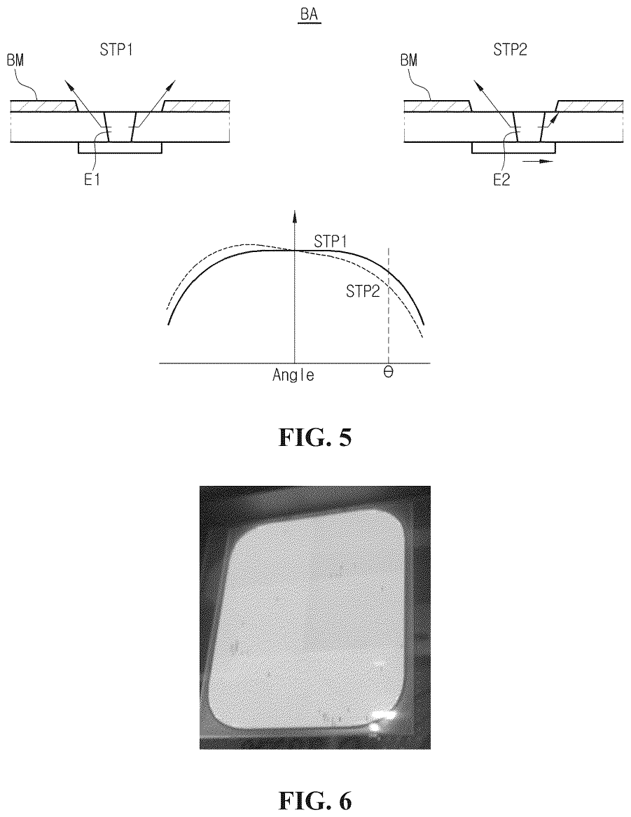

A difference in a luminance (wavelength) distribution may occur in each stamp area. Alternatively, different distortion components may exist inside the stamp element, or misalignment may occur between the different stamp elements. As illustrated in FIG. 5, in the boundary BA between the first stamp area STP1 and the second stamp area STP2, a relative position of the light emitting diode chip E1 transferred to the display panel DP using the first stamp element with respect to the black matrix BM and a relative position of the light emitting diode chip E2 transferred to the display panel DP using the second stamp element with respect to the black matrix BM can be shifted or titled.

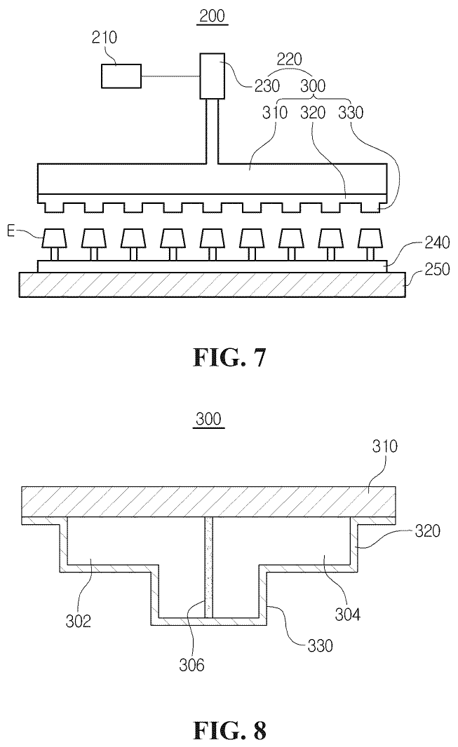

The luminance of light emitted from the light emitting diode E1, which is transferred to the display panel DP using the first stamp element with the first stamp area STP1, is different from the luminance of light emitted from the light emitting diode E2, which is transferred the display panel DP using the second stamp element with the second stamp area STP2. As illustrated in FIG. 6, due to the differences in luminance of light emitted from the light emitting diodes E1 and E2 disposed in the first stamp area STP1 and the second stamp area STP2, respectively, a clear stamp stain or mura occurs at the boundary area between the stamp areas, thereby, deteriorating image quality in the display panel DP.

In accordance with the present disclosure, it is possible to minimize or reduce stains at the boundary of the stamp areas by differently setting a half pitch between plural detachment components to which the light emitting diode E is attached by the stamp element area.

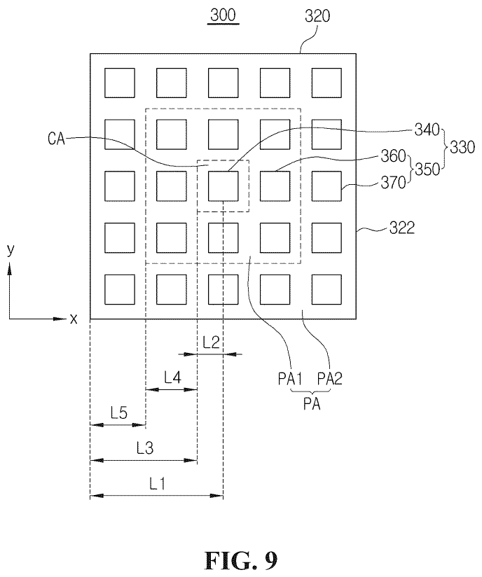

FIG. 7 illustrates a schematic light emitting diode transfer apparatus including a stamp element in accordance with one or more embodiments of the present disclosure.

Referring to FIG. 7, the light emitting diode transfer apparatus 200 includes a controller 210 that controls the transfer of the light emitting diode E and a pick-up unit 220 that picks up the light emitting diodes E (or light emitting diode chips) from the substrate 240 and puts the light emitting diodes E to another substrate.

The pick-up unit comprises a transfer arm 230 and a stamp element 300. The transfer arm 230 can be configured to move the stamp element 300. The transfer arm 230 is connected to the stamp element 300 and can move the stamp element 300 three-dimensionally by a control signal transmitted from the controller 210. The controller 210 can be configured to send a control signal to the pick-up unit 220 so that the pick-up unit 220 can lift or put each of a plurality of light emitting diodes E.

The stamp element 300 can comprise a plate connected to the transfer arm 230, a transfer head or a stamp body 230, and a plurality of detachment components 330 disposed to protrude from one surface of the transfer head 320. Another surface of the transfer head 320 can be connected to the plate 310. In FIG. 7, while the plate 310 is separated from the transfer head 320, the transfer head 330 onto which the plurality of detachment components 330 are disposed can be connected directly to the transfer arm 230 with omitting the plate 310.

The pick-up unit 220 is configured to lift the plurality of light emitting diodes E arranged on the substrate 240 and to transfer the selected light emitting diode E on another substrate. The pick-up unit 220 may transfer selectively the light emitting diode E. For example, the pick-up unit 220 can be configured to lift at least a portion of the plurality of light emitting diodes E arranged on the substrate 240 by a control signal received from the controller 210 and to put or lower the light emitting diode E selected from at least a portion of the light emitting diodes E on another substrate (e.g., display panel).

The stamp element 300 can have a structure capable of independently transferring the plurality of light emitting diodes E. The stamp element 300 can have the plurality of detachment components 330 configured to lift and lower the plurality of light emitting diodes E by contacting each of the plurality of light emitting diodes E.

The substrate 240 in FIG. 7 can be any substrate prior to transferring the light emitting diode E. For example, the substrate 240 can be a growth substrate where the plurality of light emitting diodes E are generated or a moving substrate prior to transferring the light emitting diodes E are transferred to the display panel. A supporter 250 configured to allow the substrate 240 or another substrate to be disposed thereon can be disposed.

In FIG. 7, one light emitting diode E is attached to each of the plurality of detachment components 330. In another embodiment, the number of light emitting diodes corresponding to the number of sub-pixels may be attached to each of the detachment components 330. For example, light emitting diode E may have a width of about 1 μm to about 100 μm, and have a maximum width of about 20 μm, about 10 μm or about 5 μm, but is not limited thereto.

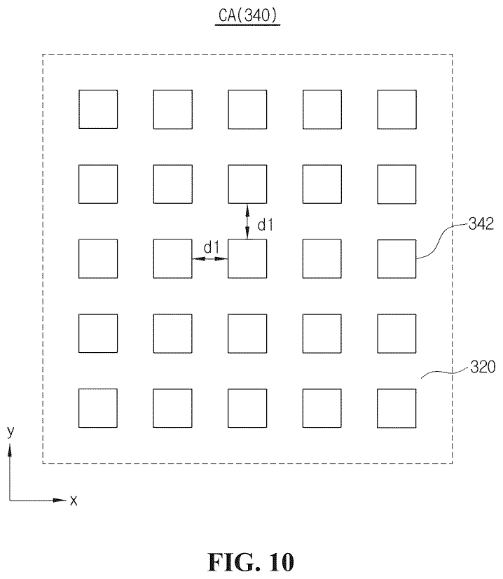

FIG. 8 illustrates a schematic configuration of a transfer head and one detachment component in the stamp element in accordance with one or more embodiments of the present disclosure.

Referring to FIG. 8, the detachment component 330 is disposed to protrude from one surface of the transfer head 320. The transfer head 320 and the detachment component 330 can comprise a first stamp electrode 302, a second stamp electrode 304 spaced apart from the first stamp electrode 302 and a stamp insulating layer 306 disposed between the first stamp electrode 302 and the second stamp electrode 304. As electricity is applied to the first stamp electrode 302 and the second stamp electrode 304, the light emitting diode E can be lifted from the substrate 240 or put on a target substrate such as the display panel.

For example, the first stamp electrode 302 and the second stamp electrode 304 can comprise silicon (Si), and the stamp insulating layer 306 can comprise aluminum oxide (Al₂O₃), but is not limited thereto. The surface of the transfer head 320 and the detachment component 330 can comprise aluminum oxide (Al₂O₃), but is not limited thereto.

In FIG. 8, the first stamp electrode 302 and the second stamp electrode 304 are disposed on left side and right side of the stamp element 300, respectively. In another embodiment, the first stamp electrode and the second stamp electrode can be disposed on an upper surface and a lower surface of the stamp element 300, respectively, and the stamp insulating layer can be disposed therebetween.

An adhesive component can be disposed at an end of the detachment component 330. For example, the adhesive component can be attached to the detachment component 330 using a photosensitive adhesive composition that can be patterned. In addition, magnetic means can be further configured to the stamp element 300. The detachment component 330 can lift or lower each of the light emitting diodes E using electrostatic force, magnetic force and/or Van der Waals force.

In another embodiment, the stamp element 330 can be a hybrid electrostatic-elastic polymer stamp element. For example, the transfer head 320 and/or the detachment component 330 can comprise, but is not limited to, rubber and/or a silicone-containing elastic polymer such as polydimethyl siloxane (PDMS).

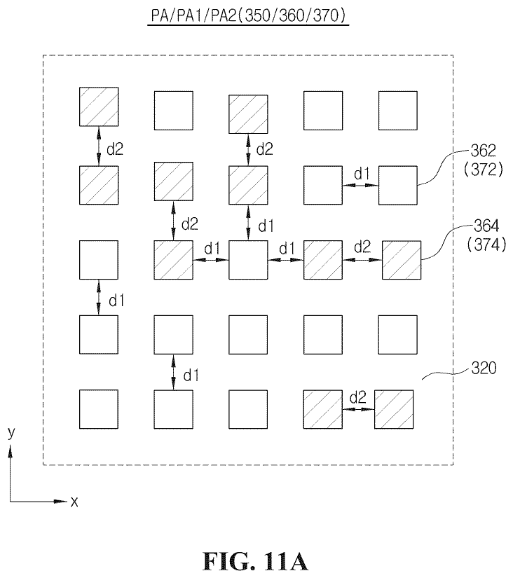

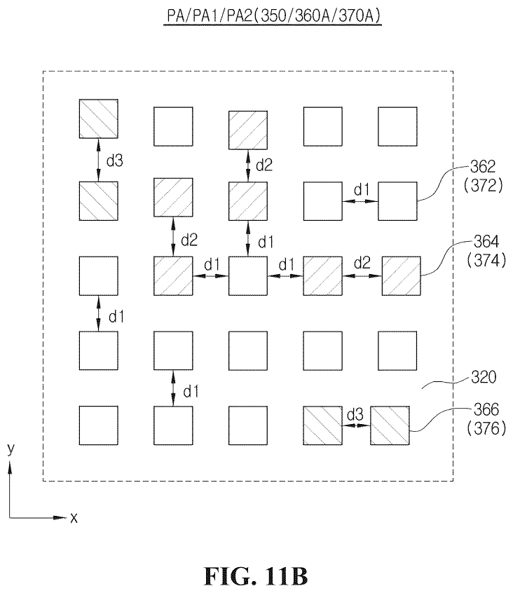

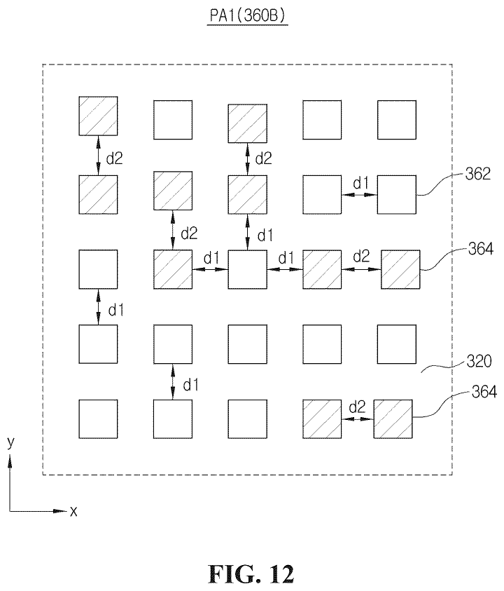

FIG. 9 illustrates a schematic arrangement of plural detachment components disposed on one surface of the transfer head in the stamp element in accordance with one or more embodiments of the present disclosure. FIG. 10 illustrates a schematic arrangement of plural detachment components disposed in a central area of the transfer head in the stamp element in accordance with one or more embodiments of the present disclosure. FIGS. 11A and 11B illustrate a schematic arrangement of plural detachment components in a peripheral area of the transfer head in the stamp element in accordance with one embodiment of the present disclosure. In FIGS. 11A and 11B, among the detachment components disposed in the peripheral area of the transfer head, detachment components having a separation distance different from a separation distance of detachment components disposed in the central area are illustrated differently, and the same is illustrated in the following drawings.

Referring to FIG. 9, one surface of the transfer head 320 can comprise the central area CA and the peripheral area PA between the central area CA and an edge 322 thereof. The peripheral area PA can be an area enclosing or surrounding the central area CA. The transfer head 320 may have a first distance L1 from the center thereof to the edge 322 thereof. In one embodiment, the central area CA of the transfer head 320 may be an area within a second distance L2 from the center of the transfer head 320.

An area from the outside of the central area CA of the transfer head 320 to the edge 322 of the transfer head 320 may be defined as the peripheral area PA of the transfer head 320. The peripheral area PA of the transfer head 320 may be an area extending from the central area CA of the transfer head 320 to the edge 322 of the transfer head 320 having a third distance L3. For example, each of the second distance L2 and the third distance L3 may be ⅕ to ⅘, for example, ¼ to ¾, ⅓ to ⅔ or ½ with respect to the first distance L1, but is not limited thereto.

In one embodiment, the peripheral area PA on one surface of the transfer head 320 can comprise a first peripheral area PA1 relatively adjacent to the central area CA of the transfer head 320 and a second peripheral area PA2 relatively adjacent to the edge 322 of the transfer head 320.

The first peripheral area PA1 of the transfer head 320 may be an area having a fourth distance L4 from the outside of the central area CA of the transfer head 320. The second peripheral area PA2 of the transfer head 320 may b3 an area extending from the outside of the first peripheral area PA1 of the transfer head 320 to the edge 322 of the transfer head 320 having a fifth distance L5.

For example, each of the fourth distance LA and the fifth distance L5 may be ⅕ to ⅘, for example, ¼ to ¾, ⅓ to ⅔ or ½ with respect to the third distance L3, but is not limited thereto. In another embodiment, the peripheral area PA on one surface of the transfer head 320 can be divided into a plurality of peripheral areas defined between the central area CA of the transfer head 320 and the edge 322 of the transfer head 320.

With respect to the present disclosure, the first peripheral area PA1 is an area relatively adjacent to the central area CA, and the second peripheral area PA2 is an area relatively adjacent to the edge 322. In FIG. 9, the first peripheral area PA1 and the second peripheral area PA2 are continuously located. In another embodiment, the first peripheral area PA1 and the second peripheral area PA2 can be discontinuously located.

In the drawings, the transfer head 320 and the detachment components 330, 340, 350, 360 and 370 has a square rear shape. In another embodiment, the transfer head 320 and/or the detachment components 330, 340, 350, 360 and 370 may have a rectangular, elliptical or circular rear shape. For example, the detachment components 330, 340, 350, 360 and 370 may have a cylindrical, conical and/or polygonal column cross section, but is not limited thereto.

A plurality of central detachment components 340 are disposed in the central area CA of the transfer head 320, and a plurality of peripheral detachment components 350 are disposed in the peripheral area PA of the transfer head 320. For example, a plurality of first peripheral detachment components 360 are disposed in the first peripheral area PA1 and a plurality of second peripheral detachment components 370 are disposed in the second peripheral area PA2.

The plurality of central detachment components 340 comprise a plurality of first detachment components 342 disposed or arranged with a first separation distance d1 (FIG. 10). In one embodiment, all the plurality of central detachment components 340 disposed in the central area CA of the transfer head 320 may be the first detachment components 342 disposed with the same first separation distance d1.

On the contrary, the plurality of peripheral detachment components 350, 360 and 370 disposed in the peripheral areas PA, PA1 and PA2 can comprise a plurality of first detachment components 362 and 372 disposed with the first separation distance d1 and a plurality of second detachment components 364 and 374 disposed with a second separation distance d2 (FIGS. 11A and 11B). In other words, at least portions of the plurality of peripheral detachment components 350, 360 and 370 disposed in the peripheral area PA, PA1 and PA2 of the transfer head 320 may be the second detachment components 364 and 374 disposed with the second separation distance d2 different from the first separation distance d1 of the plurality of the central detachment components 340 disposed in the central area CA of the transfer head 320.

The second separation distance d2 can be greater or smaller than the first separation distance d1. For example, the second separation distance d2 may be greater or smaller than the first separation distance d1 by about 0.1 μm to about 5.0 μm, for example, about 0.2 μm to about 2.0 μm or about 0.2 μm to about 1.0 μm, but is not limited thereto.

In one embodiment, all the second separation distance d2 may be greater than the first separation distance d1. In another embodiment, all the second separation distance d2 may be smaller than the first separation distance d1. In another embodiment, a portion of the second separation distance d2 may be greater than the first separation distance d1 and another portion of the second distance d2 may be smaller than the first separation distance d1.

For example, the second separation distance d2 between the second detachment components 364 and 374 may be set or designed differently within the range of the second separation distance d2 described above, such as +0.1 μm, +0.2 μm, +0.4 μm, +0.6 μm, +0.8 μm and =1.0 μm compared to the first separation distance d1 between the first detachment components 362 and 372.

In FIG. 11A, at least portions of the plurality of peripheral detachment components 360 and 370 disposed in the first and second peripheral areas PA1 and PA2 have the second peripheral detachment components 364 and 374 disposed or arranged with the second separation distance d2. In another embodiment, the plurality of peripheral detachment components 360 and 370 disposed in the first and second peripheral areas PA1 and PA2 can further another detachment components having a separation distance different from the first separation distance d1 and/or the second separation distance d2.

Referring to FIG. 11B, a plurality of peripheral detachment components 360A and 370A disposed in the first and second peripheral areas PA1 and PA2 comprise the plurality of first detachment components 362 and 372 disposed with the first separation distance d1. At least portions of the plurality of peripheral detachment components 360A and 370A can comprise the plurality of second detachment components 364 and 374 disposed with the second separation distance d2 different from the first separation distance d1. In addition, at least other portions of the plurality of peripheral detachment components 360A and 360B can comprise a plurality of third detachment components 366 and 376 disposed with a third separation distance d3 different from the first separation distance d1 and the second separation distance d2.

The third separation distance d3 may be greater or smaller than the first separation distance d1 and/or the second separation distance d2. In one embodiment, the difference between the first separation distance d1 and the third separation distance d3 may be greater than the difference between the first separation distance d1 and the second separation distance d2.

For example, the third separation distance d3 may be greater or smaller than the first separation distance d1 by about 1.0 μm to about 10.0 μm, for example, about 1.0 μm to about 5.0 μm or about 1.0 μm to about 4.0 μm, but is not limited thereto.

In another embodiment, all the third separation distances d3 may be greater than the first separation distance d1 and/or the second separation distance d2. In another embodiment, all the third separation distances d3 may be smaller than the first separation distance d1 and/or the second separation distance d2. In another embodiment, a portion of the third separation distances d3 may be greater than the first separation distance d1 and/or the second separation distance d2 and another portion of the third separation distances d3 may be smaller than the first separation distance d1 and/or the second separation distance d2.

For example, the third separation distance d3 between the third detachment components 366 and 376 may be set or designed differently within the range of the third separation distance d3 described above, such as ±1.0 μm, ±1.2 μm, ±1.4 μm, ±1.6 μm, ±1.8 μm and ±2.0 μm compared to the first separation distance d1 between the first detachment components 362 and 372.

In one embodiment, a difference between an average second separation distance among the plurality of second detachment components 364 and 374, which are disposed with the second separation distance d2, and the first separation distance d1 may differ from a difference between an average third separation distance among the plurality of third detachment components 366 and 376, which are disposed with the third separation distance d3, and the first separation distance d1. For example, the difference between the average second separation distance d2 and the first separation distance d1 may be smaller than the difference between the average third separation distance d3 and the first separation distance d1.

In FIGS. 11A and 11B, the arrangements of the plurality of peripheral detachment components 360, 360A, 370 and 370A disposed in each of the first peripheral area PA1 and the second peripheral area PA2 of the transfer head 320 are substantially identical. In another embodiment, the arrangements of the plurality of peripheral detachment components disposed in the first peripheral area may differ from the arrangements of the plurality of peripheral detachment components disposed in the second peripheral area.

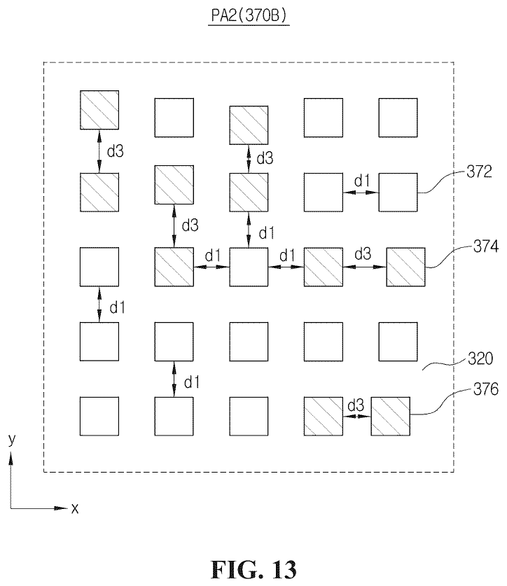

FIG. 12 illustrates a schematic arrangement of plural detachment components in the peripheral area of the transfer head in the stamp element in accordance with other embodiments of the present disclosure.

Referring to FIG. 12, a plurality of first peripheral detachment components 360B disposed in the first peripheral area PA1 of the transfer head 320 comprise the plurality of first detachment components 362 disposed with the first separation distance d1. At least portions of the plurality of first peripheral detachment components 360B comprise the plurality of second detachment components 364 disposed with the second separation distance d2 different from the first separation distance d1. In other words, at least portions of the plurality of first peripheral detachment components 360B disposed in the first peripheral area PA1 of the transfer head 320 may be the second detachment component 364 disposed with the second separation distance d2 different from the first separation distance d1.

The second separation distance d2 may be greater or smaller than the first separation distance d1. The ranges of the second separation distance d2 compared to the first separation distance d1 may be identical to the ranges referring to FIG. 11A. The second separation distance d2 among the second detachment components 364 may be differently set. The second separation distance d2 set differently compared to the first separation distance d1 may be identical to the second separation distance d2 referring to FIG. 11A.

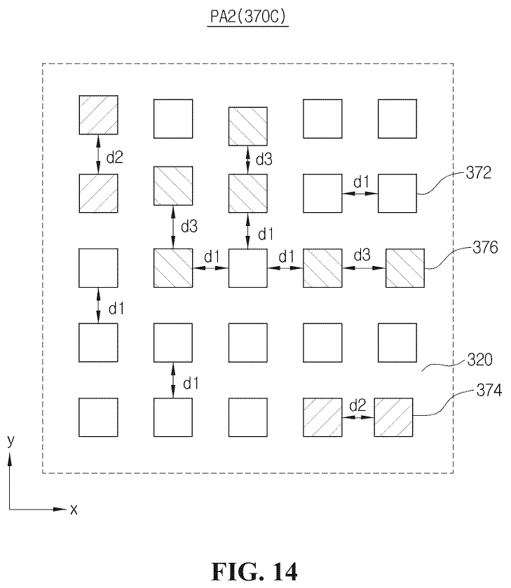

FIG. 13 illustrates a schematic arrangement of plural detachment components in the peripheral area of the transfer head in the stamp element in accordance with another embodiment of the present disclosure.

Referring to FIG. 13, a plurality of second peripheral detachment components 370B disposed in the second peripheral area PA2 of the transfer head 320 comprise the plurality of first detachment components 372 disposed with the first separation distance d1. At least portions of the plurality of second peripheral detachment components 370B comprise the plurality of third detachment components disposed with the third separation distance d2 different from the first separation distance d1. In other words, at least portions of the plurality of second peripheral detachment components 370B disposed in the second peripheral area PA2 of the transfer head 320 may be the third detachment component 376 disposed with the third separation distance d3 different from the first separation distance d1.

The third separation distance d3 may be greater or smaller than the first separation distance d1 and/or the second separation distance d2 (FIG. 12). The difference between the first separation distance d1 and the third separation distance d3 may be greater than the difference between the first separation distance d1 and the second separation distance d2. The ranges of the third separation distance d3 compared to the first separation distance d1 may be identical to the ranges referring to FIG. 11B. The third separation distance d3 among the third detachment components 376 may be differently set. The third separation distance d3 set differently compared to the first separation distance d1 may be identical to the third separation distance d3 referring to FIG. 11B.

In FIG. 13, the plurality of second peripheral detachment components 370B disposed in the second peripheral area PA2 of the transfer head 320 comprises the plurality of first detachment components 372 with the first separation distance d1 and the plurality of third detachment components 376 with the third separation distance d2. In another embodiment, the second peripheral detachment components may further comprise a plurality of second peripheral detachment components with a separation distance from the first separation distance and/or the third separation distance.

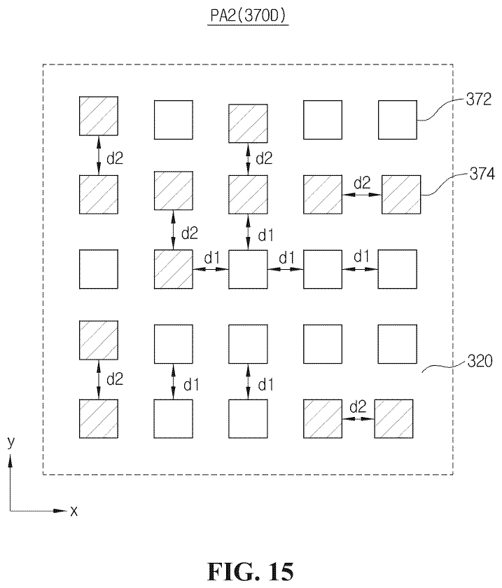

FIG. 14 illustrates a schematic arrangement of plural detachment components in the peripheral area of the transfer head in the stamp element in accordance with another embodiment of the present disclosure.

Referring to FIG. 14, a plurality of second peripheral detachment components 370C disposed in the second peripheral area PA2 of the transfer head 320 comprise the plurality of first detachment components 372 disposed with the first separation distance d1 and the plurality of third detachment components 376 disposed with the third separation distance d3. Compared to FIG. 13, the plurality of second peripheral detachment components 370C further comprise the plurality of second detachment components 374 disposed with the second separation distance d2.

At least portions of the plurality of second peripheral detachment components 370C disposed in the second peripheral area PA2 of the transfer head 320 may be the plurality of second detachment components 374 disposed with the second separation distance d2 different from the first separation distance d1, and at least other portions of the plurality of second peripheral detachment components 370C may be the plurality of third detachment components 376 disposed with the third separation distance d3 different from the first separation distance d1 and/or the second separation distance d2.

The third separation distance d3 may be greater or smaller than the first separation distance d1 and/or the second separation distance d2. For example, the difference between the first separation distance d1 and the third separation distance d3 may be greater than the difference between the first separation distance d1 and the second separation distance d2.

Each of the second separation distances d2 among the second detachment components 374 and/or each of the third separation distances d3 among the third detachment components 376 may be set identically or differently. The ranges of the second separation distance d2 and/or the ranges of the third separation distance d3 compared to the first separation distance d1, the second separation distance d2 and the third separation distance d3 set differently compared to the first separation distance d1 may be identical to the ranges and distances referring to FIGS. 11A and 11B.

In one embodiment, the difference between the average second separation distance among the plurality of second detachment components 374, which are disposed with the second separation distance d2, and the first separation distance d1 may differ from the difference between the average third separation distance among the plurality of third detachment components 376, which are disposed with the third separation distance d3, and the first separation distance d1. For example, the difference between the average second separation distance d2 and the first separation distance d1 may be smaller than the difference between the average third separation distance d3 and the first separation distance d1.

In one embodiment, compared to the third separation distance d3 among the plurality of third detachment components 376 disposed in the second peripheral area PA2 of the transfer head 320, the second separation distance d2 among the plurality of second detachment components 374 disposed in the second peripheral area PA2 of the transfer head 320 may be set close to the first separation distance d1 among the plurality of first detachment components 372.

In another embodiment, as the distance from the central area CA of the transfer head 320 increases, the plurality of peripheral detachment components 360, 360A, 360B, 370, 370A, 370B and 370C may be disposed in the first and second peripheral areas PA1 and PA2 such that the difference between the first separation distance d1 among the plurality of first detachment components 362 and 372, and the second separation distance d2 among the plurality of second detachment components 364 and 374 and/or the third separation distance d3 among the plurality of third detachment components 366 and 376 gradually increases or decreases.

The relative position of the light emitting diode E (FIG. 3) transferred to the display panel 120 (FIG. 3) is gradually shifted from the central area CA of the transfer head 320 to the edge 322 of the transfer head 320. A relative position difference of the light emitting diode E transferred to an adjacent area of the display panel 120 with respect to the black matrix 190 may be minimized or reduced. The difference in luminance of light emitted from the light emitting diode E transferred to the adjacent area of the display panel 120 is hardly recognized.

In FIGS. 12 to 14, stamp elements where the separation distance among the plurality of first peripheral detachment components 360B disposed in the first peripheral area PA1 differs from the separation distance among the plurality of second peripheral detachment components 370B and 370C disposed in the second peripheral area PA2. In another embodiment, the separation difference among the plurality of peripheral detachment components in the first peripheral area PA1 and the second peripheral area PA2 is identical, but a ratio of the detachment components with different separation distance may be set differently.

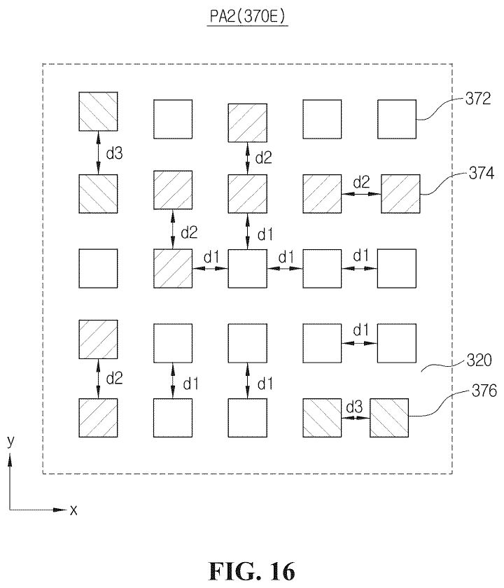

FIG. 15 illustrates a schematic arrangement of plural detachment components in the peripheral area of the transfer head in the stamp element in accordance with another embodiment of the present disclosure. The exemplary embodiment will be described referring to FIGS. 12 and 15.

As illustrated in FIG. 12, the plurality of first peripheral detachment components 360B disposed in the first peripheral area PA1 of the transfer head 320 includes the plurality of first detachment components 362 disposed with the first separation distance d1, and the plurality of second detachment components 364 disposed with the second separation distance d2. Among the plurality of first peripheral detachment components 360B disposed in the first peripheral area PA1, the number of the plurality of second detachment components 364 disposed with the second separation distance d2 is relatively small compared to the number of the plurality of first detachment components 362 disposed with the first separation distance d1.

As illustrated in FIG. 15, the plurality of second peripheral detachment components 370D disposed in the second peripheral area PA2 of the transfer head 320 includes the plurality of first detachment components 372 disposed with the first separation distance d1, and the plurality of second detachment components 374 disposed with the second separation distance d2. However, among the plurality of second peripheral detachment components 370D disposed in the second peripheral area PA2, the number of the plurality of second detachment components 374 disposed with the second separation distance d2 relatively increases compared to the number of the plurality of first detachment components 372 disposed with the first separation distance d1.

Referring to FIGS. 12 and 15, a ratio of the plurality of second detachment components 364 with the second separation distance d2 different from the first separation distance d1 among the plurality of first peripheral detachment components 360B disposed in the first peripheral area PA1 differs from a ratio of the plurality of second detachment components 374 with the second separation distance d2 different from the first separation distance d1 among the plurality of second peripheral detachment components 370D.

The ratio of the second detachment components 364 with the second separation distance d2 among the plurality of first peripheral detachment components 360B disposed in the first peripheral area PA1 may be smaller than the ratio of the second detachment components 374 with the second separation distance d2 among the plurality of second peripheral detachment components 370D disposed in the second peripheral area PA2.

For example, the ratio of the second detachment components 364 with the second separation distance d2 among the plurality of first peripheral detachment components 360B disposed in the first peripheral area PA1 may be about 1% to about 30%, for example, about 5% to about 25%, but is not limited thereto. As an example, the ratio of the second detachment components 374 with the second separation distance d2 among the plurality of second peripheral detachment components 370D disposed in the second peripheral area PA2 may be about 30% to 60%, for example, about 30% to about 50%, but is not limited thereto.

In another embodiment, the plurality of peripheral detachment components 360B and 370D may be arranged or disposed so that the ratio of the second detachment components 364 and 374 with the second separation distance d2 different from the first separation distance d1 among the plurality of peripheral detachment components 360B and 370D may gradually increase as the distance from the central area CA (FIG. 9) of the transfer head 320 increases.

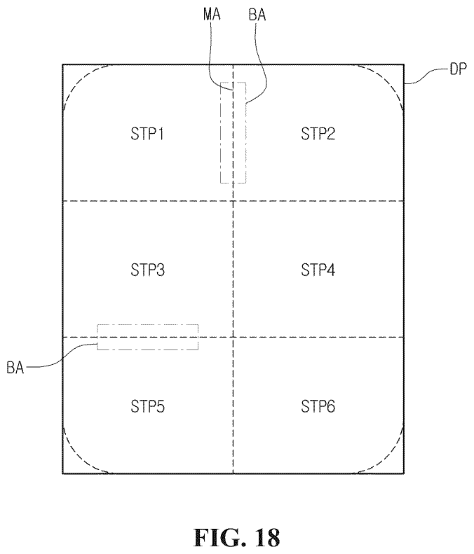

In one embodiment, all the plurality of central detachment components 340 disposed in the central area CA of the transfer head 320 may be the first detachment components 342 having the first separation distance d1. The light emitting diodes E11 and E12 (FIG. 17) attached to the plurality of central detachment components 140 disposed in the central area CA of the transfer head 320 and transferred to the display panel 120 have identical arrangement position with respect to the black matrix 190.

The ratio of the second detachment components 364 and 374 with the second separation distance d2 different from the first separation distance d1 increases toward the edge 322 of the transfer head 320. The ratio of the light emitting diodes E11 and E12 with different arrangement positions with respect to the black matrix 190 among the light emitting diodes E transferred to the adjacent area of the display panel 120 is gradually shifted. The difference in luminance of light emitted from the light emitting diodes E transferred to the adjacent area of the display panel 120 hardly recognized.

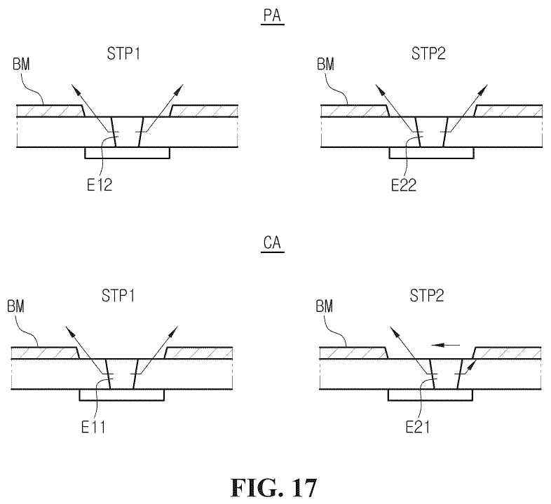

FIG. 16 illustrates a schematic arrangement of plural detachment components in the peripheral area of the transfer head in the stamp element in accordance with another embodiment of the present disclosure. The exemplary embodiment will be described referring to FIGS. 12, 15 and 16.

As illustrated in FIG. 16, the plurality of second peripheral detachment components 370E disposed or arranged in the second peripheral area PA2 of the transfer head 320 comprises the plurality of first detachment components 372 disposed with the first separation distance d1, the plurality of second detachment components 374 disposed with the second separation distance d2, and the plurality of third detachment components 376 disposed with the third separation distance d3. Compared to the arrangements of the peripheral detachment components in FIG. 12, among the plurality of second peripheral detachment components 370E disposed in the second peripheral area PA2, the number of the plurality of second detachment components 374 disposed with the second separation distance d2 and/or the number of the plurality of third detachment components 376 disposed with the third separation distance d3 increase compared to the number of the plurality of first detachment components 372 disposed with the first separation distance d1.

Referring to FIGS. 12 and 16, the ratio of the plurality of second detachment components 364 with the second separation distance d2 different from the first separation distance d1 among the plurality of first peripheral detachment components 360B disposed in the first peripheral area PA1 differs from a ratio of the plurality of second detachment components 374 and/or the plurality of third detachment components 376 with the second separation distance d2 and/or the third separation distance d3 different from the first separation distance d1 among the plurality of second peripheral detachment components 370E.

The ratio of the second detachment components 364 with the second separation distance d2 among the plurality of first peripheral detachment components 360B disposed in the first peripheral area PA1 may be smaller than the ratio of the second detachment components 374 and/or the third detachment components 376 with the second separation distance d2 and/or the third separation distance d3 among the plurality of second peripheral detachment components 370E disposed in the second peripheral area PA2.

For example, the ratio of the second detachment components 364 with the second separation distance d2 among the plurality of first peripheral detachment components 360B disposed in the first peripheral area PA1 may be about 1% to about 30%, for example, about 5% to about 25%, but is not limited thereto. As an example, the ratio of the second detachment components 374 with the second separation distance d2 and/or the third detachment components 376 with the third separation distance d3 among the plurality of second peripheral detachment components 370E disposed in the second peripheral area PA2 may be about 30% to 60%, for example, about 30% to about 50%, but is not limited thereto.

Compared to the arrangements of the second peripheral detachment components 370D in FIG. 15, the second peripheral detachment components 370E further comprises the plurality of third detachment components 376 disposed with the third separation distance d3. The third separation distance d3 may be greater or smaller than the first separation distance d1 and/or the second separation distance d2. In one embodiment, the difference between the first separation distance d1 and the third separation distance d3 may be larger than the difference between the first separation distance d1 and the second separation distance d2.

The second separation distance d2 among the plurality of second detachment components 374 and/or the third separation distance d3 among the plurality of third detachment components 376 may be set identically or differently. The ranges of the second separation distance d2 and/or the ranges of the third separation distance d3 compared to the first separation distance d1, the second separation distance d2 and the third separation distance d3 set differently compared to the first separation distance d1 may be identical to the ranges and distances referring to FIGS. 11A and 11B.

In another embodiment, the plurality of peripheral detachment components 360B and 370E may be arranged or disposed so that the ratio of the second detachment components 364 and 374 and the third detachment components 376 with the second separation distance d2 and the third separation distance d3 different from the first separation distance d1 among the plurality of peripheral detachment components 360B and 370E may gradually increase as the distance from the central area CA (FIG. 9) of the transfer head 320 increases.

The relative position of the light emitting diode E (FIG. 3) transferred to the display panel 120 (FIG. 3) is gradually shifted from the central area CA of the transfer head 320 to the edge 322 of the transfer head 320. The ratio of the second detachment components 364 and 374 and/or the third detachment components 376 with the second separation distance d2 and/or the third separation distance d3 different from the first separation distance d1 increases toward the edge 322 of the transfer head 320.

The ratio of the light emitting diodes E12 and E12 having different alignment positions with respect to the black matrix 190 in the light emitting diodes E transferred to the adjacent area of the display panel 120 gradually changed. With respect to the black matrix 190, the relative position difference among the light emitting diode E12 and E22 transferred to the adjacent area of the display panel 120 may be minimized or reduced, and therefore, the difference in luminance of light emitted from the light emitting diodes E12 and E22 transferred to the adjacent area of the display panel 120 is hardly recognized.

Table 1 below shows the arrangements of the plurality of detachment components in which the separation distances are differently set by the region of transfer head in accordance with exemplary embodiment of the present disclosure. In Table 1, the position represents the distance from the edge of the transfer head, and X and Y shifts represents the relative separation distance among the detachment components shifted to have different separation distances along the X and Y axes of the transfer head, and the relative ratio of the detachment components with different separation distance among the detachment components in the central area of the transfer head.

TABLE 1
Setting of Separation Distances among Detachment Components in Stamp Element

| Position (mm) | 10 | 9 | 8 | 7 | 6 | 5 | 4 | 3 | 2 | 1 |
|---|---|---|---|---|---|---|---|---|---|---|
| X, Y shift | 5% | 10% | 15% | 20% | 25% | 30% | 35% | 40% | 45% | 50% |
| ±0.2 μm | 2.5% | 3.5% | 5.0% | 6.5% | 8.0% | 9.5% | 11.0% | 12.5% | 14.0% | 15.5% |
| ±0.4 μm | 2.5% | 3.5% | 5.0% | 6.5% | 8.0% | 9.5% | 11.0% | 12.5% | 14.0% | 15.5% |
| ±0.6 μm | | 1.5% | 2.5% | 3.0% | 3.5% | 4.0% | 4.5% | 4.5% | 5.0% | 5.5% |
| ±0.8 μm | | 1.5% | 2.5% | 3.0% | 3.5% | 4.0% | 4.5% | 4.5% | 5.0% | 5.5% |
| ±1.0 μm | | | | 0.5% | 1.0% | 1.5% | 1.5% | 2.0% | 2.0% | 2.5% |
| ±1.2 μm | | | | 0.5% | 1.0% | 1.5% | 1.5% | 2.0% | 2.0% | 2.5% |
| ±1.4 μm | | | | | | | 0.5% | 1.0% | 1.0% | 1.0% |
| ±1.6 μm | | | | | | | 0.5% | 1.0% | 1.0% | 1.0% |
| ±1.8 μm | — | | | | | | | | 0.5% | 0.5% |
| ±2.0 μm | — | | | | | | | | 0.5% | 0.5% |

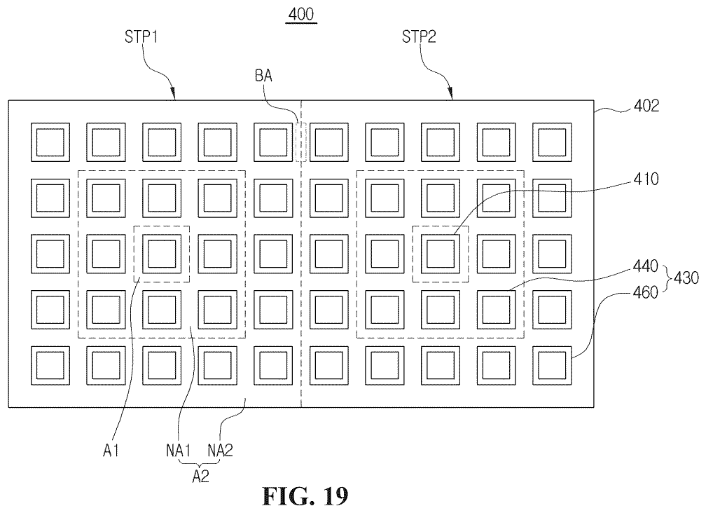

The plurality of detachment components 340, 350, 360 and 370 with different separate distances by the area of the transfer head 320 are arranged by the above embodiments, the stains in the boundary area BA (FIG. 18) among the stamp areas can be minimized or reduced. FIG. 17 illustrates a schematic diagram illustrating an alignment of the light emitting diode chip matches in the boundary area of stamp areas when the light emitting diode is transferred to the display panel using the stamp element in accordance with one or more embodiments of the present disclosure. FIG. 18 illustrates a schematic diagram illustrating a mura or a stain is hardly visible by the match of light luminance in the boundary area of the stamp area when the light emitting diode is transferred to the display panel using the stamp element in accordance with one or more embodiments of the present disclosure.

Referring to FIG. 17, the relative arrangement locations of the light emitting diodes E11 and E12 with respect to the black matrix BM in the central area CA of each of the first stamp area STP1 and the second stamp area STP2 may be different from each other. According to the above embodiments and examples, the central detachment components 340 disposed in the central area CA of each of the stamp area STP1 and STP2 includes only the first detachment components 342 with the same first separation distance d1.

On the contrary, the peripheral detachment components 350, 360 and 370 disposed in the peripheral area PA of each of the first and second stamp areas STP1 and STP2 includes the first detachment components 362 and 372 with the first separation distance d1 as well as the second detachment components 364 and 374 and/or the third detachment components 366 and 376 with the second separation distance d2 and/or the third separation distance different from the first separation distance d1.

The first detachment components 362 and 372, which are at least portions of the peripheral detachment components 360 and 370 disposed in the peripheral area PA within the first stamp area STP1, may have the same first separation distance as the first detachment component 342 disposed in the central area CA. Accordingly, the alignment position with respect to the black matrix BM of the light emitting diode E12, which is attached to the first detachment components 362 and 372 disposed in the peripheral area PA within the first stamp area STP1 and transferred to the display panel DP, may be the same as the alignment position with respected to the black matrix BM of the light emitting diode E11, which is attached to the first detachment components 342 disposed in the central area CA within the first stamp area STP1 and transferred to the display panel DP.

On the other hand, the second and/or the third detachment components 364, 374, 366 and 376, which are at least potions of the peripheral detachment components 360 and 370 disposed in the peripheral area PA within the second stamp area STP2, have second and/or third separation distance distances d2 and/or d3 different from the first separation distance d1 of the first detachment components 342 disposed in the central area CA. Accordingly, the alignment positions with respect to the black matrix BM of the light emitting diode E22, which is attached to the second and third detachment components 364, 374, 366 and 376 disposed in the peripheral area PA within the second stamp area STP2 and transferred to the display panel DP, may be shifted from the alignment position with respected to the black matrix BM of the light emitting diode E21, which is attached to the first detachment components 342 disposed in the central area CA within the second stamp area STP2 and transferred to the display panel DP.

Accordingly, the alignment position of the light emitting diode E12 with respect to the black matrix BM in at least portions of the peripheral area PA within the first stamp area STP1 coincides with the alignment position of the light emitting diode E22 with respect to the black matrix BM in at least portions of the peripheral area PA within the second stamp area STP2.

In the area MA where the alignment positions of the light emitting diodes E12 and E22 respect to the black matrix BM match among the boundary area BA between the first stamp area STP1 and the second stamp area STP2, since the luminance of light emitted from the light emitting diode E12 disposed in the first stamp area STP1 is the same as the luminance of light emitted from the light emitting diode E22 disposed in the second stamp area STP2, the luminance difference is not recognized. In the area MA where the alignment positions of the light emitting diodes E12 and E22 respect to the black matrix BM match among the boundary area BA between the first stamp area STP1 and the second stamp area STP2, stamp stains due to the luminance difference do not occur. It is possible to implement a display device with improved image quality by minimizing or reducing stains due to the difference in luminance of light at the boundary area BA among the stamp areas STP1 to SPT6.

In the above-described embodiments and examples, the alignment position of the light emitting diode with respect to the black matrix is shifted according to areas by controlling the separation distances among the plurality of detachment portions to which the light emitting diodes are attached. In another embodiment, the alignment position of the black matrix with respect to the light emitting diode may be shifted by adjusting line widths of black matrix patterns, which will be described.

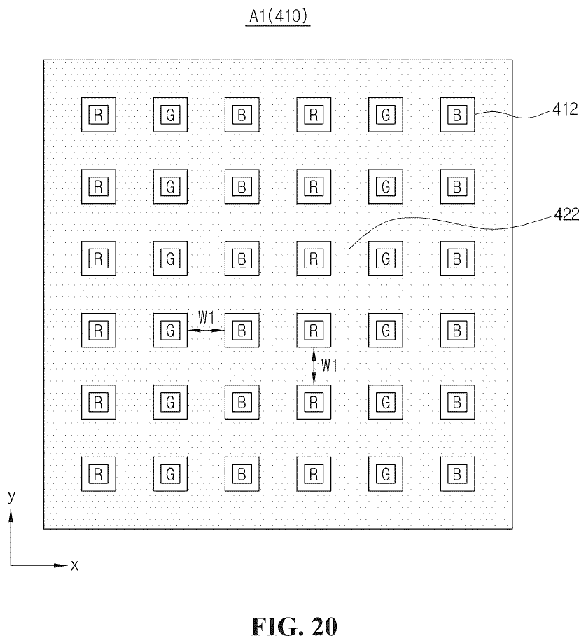

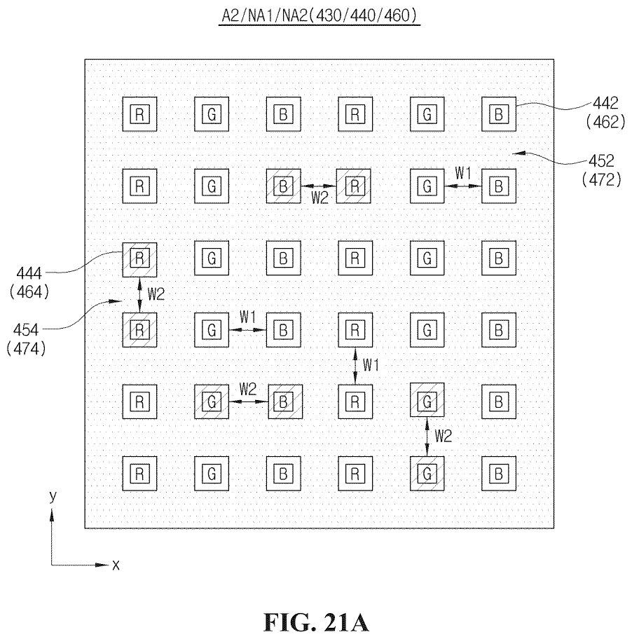

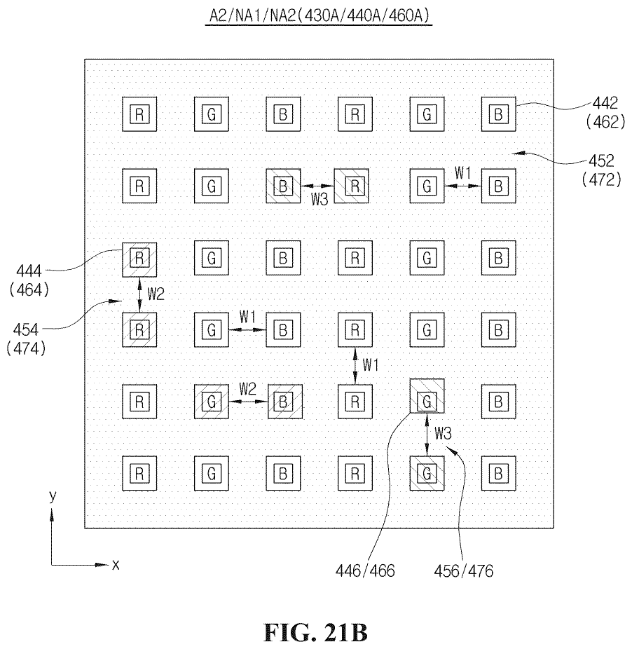

FIG. 19 illustrates a schematic arrangement of black matrix patterns in accordance with one or more embodiments of the present disclosure. FIG. 20 illustrates a schematic arrangement of black matrix patterns in a first area in accordance with one or more embodiments of the present disclosure. FIGS. 21A and 21B illustrate a schematic arrangement of black matrix patterns in a second area in accordance with one embodiment of the present disclosure. In FIG. 19, two stamp areas STP1 and STP2 and the boundary area BA between the stamp areas STP1 and STP2 are illustrated. In FIG. 19, plural light blocking patterns are divided in each area, it is to be understood that the plural light blocking patterns are disposed or arranged continuously. In FIGS. 21A and 21B, among the plural light blocking patterns in a second area, light blocking patterns having a different line width different from a line width of light blocking patterns disposed in a first area are illustrated differently, and the same is illustrated in the following drawings.

Referring to FIGS. 19 to 21B, a black matrix pattern 400, which is corresponds to each of the first and second stamp areas STP1 and STP2, may have a first area A1, and a second area A2 between the first area A1 and the second stamp area STP2 or between the first area A1 and an edge 402 of the black matrix pattern 400. The second area A2 may be an area enclosing or surrounding the first area A1.

For example, the first area A1 may be an area corresponding to the central area CA of the transfer head 320 (FIG. 9), and the second area A2 may be an area corresponding to the peripheral area PA of the transfer head 320 (FIG. 9). The relative size or dimension of the first area A1 and the second area A2 in each of the first and second stamp areas STP1 and STP2 may be the same as the size or dimension of the central area CA and the peripheral area PA of the transfer head 320 referring to FIG. 9.

In one embodiment, the second area A2 of the black matrix pattern 400 can comprise a first adjacent area NA1 enclosing the first area A1, and a second adjacent area NA2 enclosing the first adjacent area NA2. For example, the first adjacent area NA1 may be an area corresponding to the first peripheral area PA1 on the transfer head 320 (FIG. 9), and the second adjacent area NA2 may be an area corresponding to the second peripheral area PA2 on the transfer head 320 (FIG. 9).

In one embodiment, the relative size or dimension of the first adjacent area NA1 and the second adjacent area NA2 in the first stamp area STP2 may be the same as the first peripheral area PA1 and the second peripheral area PA2, respectively, referring to FIG. 9. In another embodiment, the second area A2 may be divided into a plurality of adjacent areas defined between the first area A1 to the edge 420 of the black matrix pattern 400 or between the first area A1 and the boundary area BA of the adjacent second stamp area STP2.

With respect to the present disclosure, the first adjacent area NA1 is an area relatively adjacent to the first area A1, and the second adjacent area NA2 is an area relatively adjacent to the edge 402 or the boundary area BA. In FIG. 19, the first adjacent area NA1 and the second adjacent area NA2 are continuously located. In another embodiment, the first adjacent area NA1 and the second adjacent area NA2 can be discontinuously located.

A plurality of first area light blocking patterns 410 enclosing a plurality of first openings 412, respectively, are disposed or arranged in the first area A1. A plurality of second area light blocking patterns 430 enclosing a plurality of openings 442, 462, 444 and 464, respectively, are disposed or arranged in the second area A2.

For example, the plurality of second area light blocking patterns 430 can comprise a plurality of first adjacent area light blocking patterns 440 disposed to enclose each of the plurality of openings 442, 444 and 446 in the first adjacent area NA1 and a plurality of second adjacent area light blocking patterns 460 disposed to enclose each of the plurality of opening 462, 464 and 466 in the second adjacent area NA2.

The plurality of first area light blocking patterns 410 positioned in the first area A1 comprise a plurality of first light blocking patterns 422 enclosing each of the plurality of first openings 412. The plurality of first light blocking patterns 422 constituting the plurality of first area light blocking patterns 410 enclose each first opening 412 with a first line width W1. In other words, each first opening 412 is disposed or arranged at a distance corresponding to the first line width W1 of the first light blocking pattern 422 with respect to the adjacent first opening 412 in the first area A1.

On the contrary, the plurality of second area light blocking patterns 430, 440 and 460 arranged in the second area NA, NA1 or NA2 can comprise a plurality of first light blocking patterns 452 and 472 enclosing each of the first openings 442 and 462 and a plurality of second light blocking patterns 454 and 474 enclosing each of the second openings 444 and 464. The plurality of first light blocking patterns 452 and 472 surround each of the first openings 442 and 462 with the first line width W1 and the plurality of second light blocking patterns 454 and 474 surround each of the second openings 444 and 446 with a second line width W2 different from the first line width W1.

In other words, each first opening 442 or 462 is disposed or arranged at a distance corresponding to the first line width W1 of the first light blocking pattern 452 or 472 with respect to the adjacent first opening 442 or 462 in the second area A2, NA1 or NA2. Each second opening 444 and 464 is disposed or arranged at a distance corresponding to the second line width W2 of the second light blocking pattern 454 or 474 with respect to the adjacent second opening 444 or 464 in the second area A2, NA1 or NA2.

The second line width W2 can be greater or smaller than the first line width W1. For example, the second line width W2 may be greater or smaller than the first line width W1 by about 0.1 μm to about 5.0 μm, for example, about 0.2 μm to about 2.0 μm or about 0.2 μm to about 1.0 μm, but is not limited thereto.

In one embodiment, all the second line widths W2 may be greater than the first line width W1. In another embodiment, all the second line widths W2 may be smaller than the first line width W1. In another embodiment, a portion of the second line width W2 may be greater than the first line width W1 and another portion of the second line width W2 may be smaller than the first line width W1.

For example, the second line width W2 of the second light blocking patterns 454 and 474 corresponding to the separation distance between the second openings 444 and 464 may be set differently within the range of the second line width W2 described above, such as +0.1 μm, +0.2 μm, +0.4 μm, +0.6 μm, +0.8 μm and +1.0 μm compared to the first line width W1 of the first light blocking patterns 452 and 472 corresponding to the separation distance between the first openings 442 and 462.

In FIG. 21A, at least portions of the plurality of second area light blocking patterns 430, 440 and 460 disposed in the first and second adjacent areas NA1 and NA2 have the second light blocking patterns 454 and 474 disposed or arranged with the second line width W2. In another embodiment, the plurality of second area light blocking patterns 430, 440 and 460 disposed in the first and second adjacent areas NA1 and NA2 can further another light blocking patterns having a line width different from the first line width W1 and/or the second line width W2.

Referring to FIG. 21B, a plurality of second area light blocking patterns 430A, 440A and 460A disposed in the first and second adjacent areas NA1 and NA2 comprise the plurality of first light blocking patterns 452 and 472 enclosing each of the plurality of first openings 442 and 462 with the first line width W1. In addition, the plurality second area light blocking light patterns 430A, 440A and 460A can comprise the plurality of second light blocking patterns 454 and 474 enclosing each of the plurality of second openings 444 and 464 and a plurality of third light blocking patterns 456 and 476 enclosing each of a plurality of third openings 446 and 466 with a third line width W3. The plurality of third light blocking patterns 456 and 476 may be disposed or arranged to enclose each third opening 446 or 466 with the third line width W3 different from the first line width W1 and/or the second line width W2.

Each of the first openings 442 and 462 is disposed with a distance corresponding to the first line width W1 of the first light blocking pattern 452 or 472 with respect to the adjacent first openings 442 and 462 in the second areas A2, NA1 and NA2. Each of the second openings 444 and 464 is disposed with a distance corresponding to the second line width W2 of the second light blocking pattern 454 or 472 with respect to the adjacent second openings 444 and 464 in the second areas A2, NA1 and NA2. Each of the third openings 446 and 466 is disposed with a distance corresponding to the third line width W3 of the third light blocking pattern 456 or 476 with respect to the adjacent third openings 446 and 466 in the second areas A2, NA1 and NA2.

The third line width W3 may be greater or smaller than the first line width W1 and/or the second line width W2. In one embodiment, the difference between the first line width W1 and the third line width W3 may be greater than the difference between the first line width W1 and the second line width W2.

For example, the third line width W3 may be greater or smaller than the first line width W1 by about 1.0 μm to about 10.0 μm, for example, about 1.0 μm to about 5.0 μm or about 1.0 μm to about 4.0 μm, but is not limited thereto.

In another embodiment, all the third line width W3 may be greater than the first line width W1 d1 and/or the second line width W2. In another embodiment, all the third line width W3 may be smaller than the first line width W1 and/or the second line width W2. In another embodiment, a portion of the third line width W3 may be greater than the first line width W1 and/or the second line width W2 and another portion of the third line width W3 may be smaller than the first line width W1 and/or the second line width W2.

For example, the third line width W3 of the plurality of third light blocking patterns 456 and 476, which is corresponding to a separation distance between the plurality of third openings 446 and 466, may be set or designed differently within the range of the third line width W3 described above, such as #1.0 μm, +1.2 μm, +1.4 μm, +1.6 μm, +1.8 μm and +2.0 μm compared to the first line width W1 of the plurality of first light blocking patterns 452 and 472, which is corresponding to the separation distance between the plurality of first openings 442 and 462.

In one embodiment, a difference between an average second line width W2 corresponding to an average separation distance of the second openings 444 and 464 and the first line width W1 may differ from a difference between an average third line width W3 corresponding to an average separation distance of the third openings 446 and 466 and the first line width W1. For example, the difference between the average second line width W2 and the first line width W1 may be smaller than the difference between the average third line width W3 and the first line width W1.

In FIGS. 21A and 21B, the arrangements of the plurality of second area light blocking patterns 440, 440A, 460 and 460B disposed to enclose the plurality openings 442, 444, 462 and 464 in each of the first adjacent area NA1 and the second adjacent area NA2 within the black matrix pattern 400 (FIG. 19) are substantially identical. In another embodiment, the arrangements of the plurality of second area light blocking patterns disposed in the first adjacent area may differ from the arrangements of the plurality of second area light blocking patterns disposed in the second adjacent area.

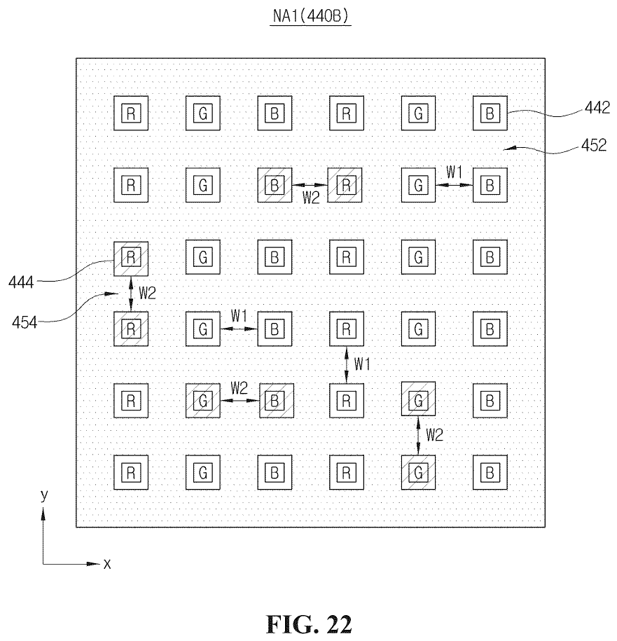

FIG. 22 illustrates a schematic arrangement of black matrix patterns in a first adjacent area in accordance with one or embodiments of the present disclosure.

Referring to FIG. 22, a plurality of first adjacent area light blocking patterns 440B disposed in the first adjacent area NA1 of the black matrix pattern 400 can comprise the plurality of first light blocking patterns 452 enclosing each of the plurality of first opening 442 and the plurality of second light blocking patterns 454 enclosing each of the plurality of second openings 444. The plurality of first light blocking patterns 452 encloses each of the first openings 442 with the first line width W1 and the plurality of second light blocking patterns 454 encloses each of the second openings 444 with the second line width W2 different from the first line width W1. In other words, at least portions of the plurality of first adjacent light blocking patterns 440B disposed in the first adjacent area NA1 may be the second light blocking patterns 454 disposed with the second line width W2 different from the first line width W1.

The second line width W2 may be greater or smaller than the first line width W1. The ranges of the second line width W2 compared to the first line width W1 may be identical to the ranges referring to FIG. 21A. The second line width W2 of the separation distance the second openings 444 may be differently set. The second line width W2 set differently compared to the first line width W1 may be identical to the second line width W2 referring to FIG. 21A.

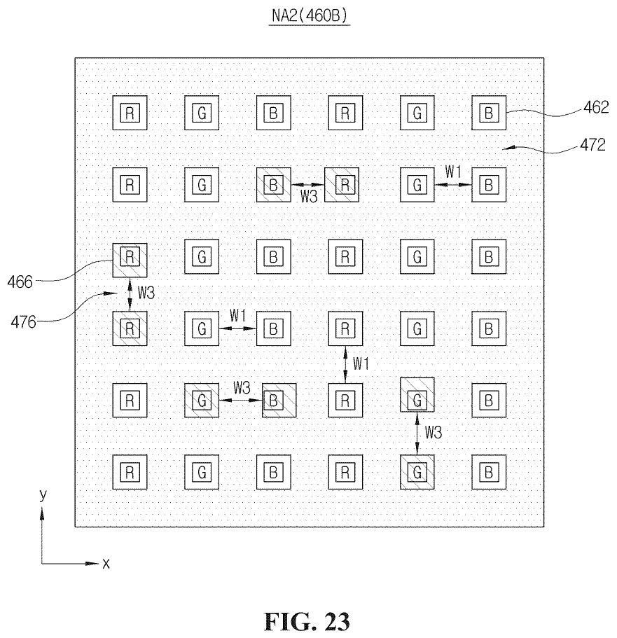

FIG. 23 illustrates a schematic arrangement of black matrix patterns in a second adjacent area in accordance with another embodiment of the present disclosure.

Referring to FIG. 23, a plurality of second adjacent area light blocking patterns 460B disposed in the second adjacent area NA2 comprise the plurality of first light blocking patterns 472 enclosing each of the plurality of first openings 462 and the plurality of third light blocking patterns 476 enclosing each of the plurality of third openings 466. The plurality of first light blocking patterns 472 encloses each of the first openings 462 with the first line width W1 and the plurality of third light blocking patterns 476 encloses each of the third openings 466 with the third line width W3 different from the first line width W1. At least portions of the plurality of second adjacent area light blocking patterns 460B disposed in the second adjacent area NA2 may be the third light blocking patterns 476 disposed with the third line width W3 different from the first line width W1.

The third line width W3 may be greater or smaller than the first line width W1 and/or the second line width W2 (FIG. 22). The difference between the first line width W1 and the third line width W3 may be greater than the difference between the first line width W1 and the second line width W2. The ranges of the third line width W3 compared to the first line width W1 may be identical to the ranges referring to FIG. 21B. The third line width W3 of the separation distance between the third openings 476 may be differently set. The third line width W3 set differently compared to the first line width W1 may be identical to the third line width W3 referring to FIG. 21B.

In FIG. 23, the plurality of second adjacent area light blocking patterns 460B disposed in the second adjacent area NA2 of the black matrix pattern 400 comprise the plurality of first light blocking patterns 472 enclosing each of the first openings 462 with the first line width W1 and the plurality of third light blocking patterns 476 enclosing each of the third openings 466 with the third line width W3. In another embodiment, the second adjacent area light blocking patterns may further comprise a plurality of second light blocking patterns with a line width different from the first line width and/or the third line width.

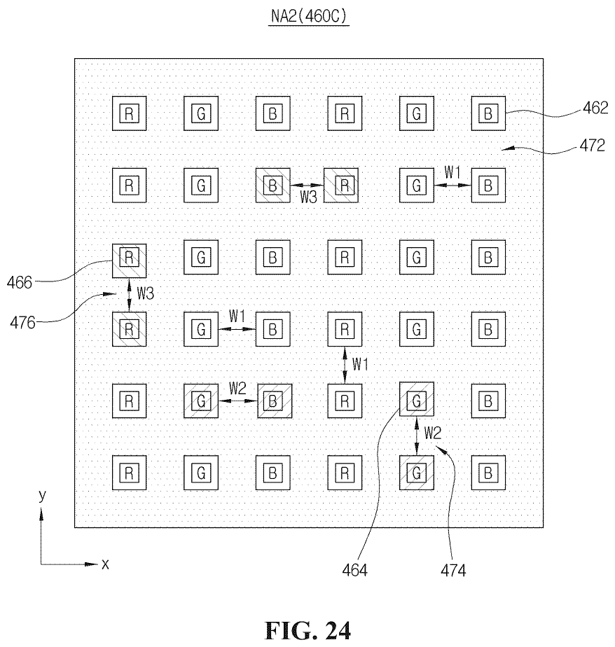

FIG. 24 illustrates a schematic arrangement of black matrix patterns in a second adjacent area in accordance with another embodiment of the present disclosure.

Referring to FIG. 24, a plurality of second adjacent area light blocking patterns 460C disposed in the second adjacent area NA2 of the black matrix pattern 400 comprises the plurality of first light blocking patterns 472 enclosing each of the plurality of first openings 462, the plurality of second light blocking patterns 472 enclosing each of the plurality of second openings 464 and the plurality of third light blocking patterns 476 enclosing each of the plurality of third openings 466. Compared to FIG. 23, the plurality of second adjacent area light blocking patterns 460C further comprise the plurality of second light blocking patterns 474 disposed to enclose each of the second openings 464.

At least portions of the plurality of second adjacent light blocking patterns 460C disposed in the second adjacent area NA2 of the black matrix pattern 400 may be the plurality of second light blocking patterns 474 disposed with the second line width W2 different from the first line width W1, and at least other portions of the plurality of second adjacent light blocking patterns 460C may be the plurality of third light blocking patterns 476 disposed with the third line width W3 different from the first line width W1 and/or the second line width W2.

The third line width W3 may be greater or smaller than the first line width W1 and/or the second line width W2. For example, the difference between the first line width W1 and the third line width W3 may be greater than the difference between the first line width W1 and the second line width W2.

Each of the second line width W2 of the separation distance between the second openings 464 and/or each of the third line width W3 of the separation distances between the third opening 466 may be set identically or differently. The ranges of the second line width W2 and/or the ranges of the third line width W3 compared to the first line width W1, the second line width W2 and the third line width W3 set differently compared to the first line width W1 may be identical to the ranges and distances referring to FIGS. 21A and 21B.

In one embodiment, the difference between the average second line width W2 of an average separation distance between the second openings 464 and the first line width W1 may differ from the difference between the average third line width W3 of an average separation distance between the third openings 466 and the first line width W1. For example, the difference between the average second line width W2 and the first line width W1 may be smaller than the difference between the average third line width W3 and the first line width W1.

In one embodiment, compared to the third line width W3 between the third opening 466 disposed in the second adjacent area NA2, the second line width W2 between the second openings 464 disposed in the second adjacent area NA2 may be set close to the first line width W1 between the first openings 462.

In another embodiment, as the distance from the first area A1 of the black matrix pattern 400 increases, the plurality of second area light blocking patterns 440A, 440B, 460A, 460B and 460C may be disposed in the first and second adjacent areas NA1 and NA2 such that the difference between the first line width W1 among the first light blocking patterns 452 and 462, which is the separation distance among the first openings 442 and 462, and the second line width W2 among the second light blocking patterns 454 and 464, which is the separation distance among the second openings 444 and 464, and/or the third line width W3 among the third light blocking patterns 456 and 466, which is the separation distance among the third openings 446 and 466, gradually increases or decreases.

The relative positions of the black matrix 190 (FIG. 3) with respect to the light emitting diode E (FIG. 3) transferred to the display panel 120 (FIG. 3) is gradually shifted as the distance from the first area A1 of the black matrix pattern 400 increases. As the relative arrangement difference of the black matrix 190 with respect to the light emitting diode E transferred to the display panel 120 minimizes or reduces, the difference in luminance of light emitted from the light emitting diode E transferred to the adjacent area of the display panel 120 is hardly recognized.

In FIGS. 22 to 24, black matrix patterns where the first adjacent area light blocking patterns 440B disposed in the first adjacent area NA1 and the second adjacent area light blocking patterns 460B and 460C include the plurality line widths are described. In another embodiment, the arrangements the line width among the second area light blocking patterns in the first adjacent area NA1 and the second adjacent area NA2 is identical, but a ratio of the light blocking patterns with different line width may be set differently.

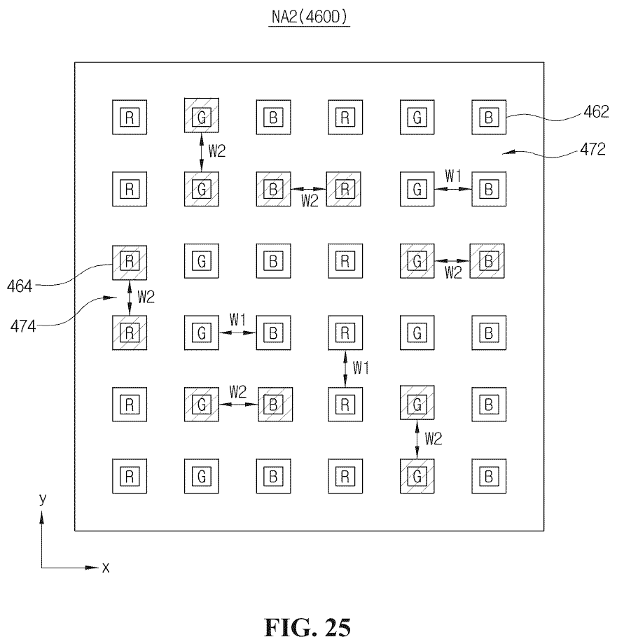

FIG. 25 illustrates a schematic arrangement of black matrix patterns in a second adjacent area in accordance with another embodiment of the present disclosure. The exemplary embodiment will be described referring to FIGS. 22 and 25.

As illustrated in FIG. 22, the plurality of first area light blocking patterns 440B disposed in the first adjacent NA1 of the black matrix pattern 400 includes the plurality of first light blocking patterns 452 enclosing each of the plurality of first openings 442 with the first line width W1, and the plurality of second light blocking patterns 454 enclosing each of the plurality of second openings 444 with the second line width W2. Among the plurality of first are light blocking patterns 440B disposed in the first adjacent area NA1, the number of the plurality of second light blocking patterns 454 disposed with the second line width W3 is relatively small compared to the number of the plurality of first light blocking patterns 452 disposed with the first line width W1.

As illustrated in FIG. 25, the plurality of second area light blocking patterns 460D disposed in the second adjacent area NA2 of the black matrix pattern 400 include the plurality of first light blocking patterns 472 enclosing each of the plurality of first openings 462 with the first line width W1, and the plurality of second light blocking patterns 474 enclosing each of the second openings 464 with the second line width W2. However, among the plurality of second adjacent area light blocking patterns 460B disposed in the second adjacent area NA2, the number of the plurality of second light blocking patterns 474 disposed with the second line width W2 relatively increases compared to the number of the plurality of first light blocking patterns 472 disposed with the first line width W1.

Referring to FIGS. 22 and 25, a ratio of the plurality of second light blocking patterns 454 with the second line width W2 different from the first line width W1 among the plurality of first area light blocking patterns 440B disposed in the first adjacent area NA1 differs from a ratio of the plurality of second blocking patterns 474 with the second line width W2 different from the first line width W1 among the plurality of second adjacent area light blocking patterns 470D.

The ratio of the second light blocking patterns 444 with the second line width W2 among the plurality of first adjacent area light blocking patterns 440B disposed in the first adjacent area NA1 may be smaller than the ratio of the second light blocking patterns 474 with the second line width W2 among the plurality of second adjacent area light blocking patterns 460D disposed in the second adjacent area NA2.

For example, the ratio of the second light blocking patterns 444 with the second line width W2 among the plurality of first adjacent area light blocking patterns 440B disposed in the first adjacent area NA1 may be about 1% to about 30%, for example, about 5% to about 25%, but is not limited thereto. As an example, the ratio of the second light blocking patterns 474 with the second line width W2 among the plurality of second adjacent area light blocking patterns 470D disposed in the second adjacent area NA2 may be about 30% to 60%, for example, about 30% to about 50%, but is not limited thereto.

In another embodiment, the plurality of second area light blocking patterns 440, 440A, 440B, 460, 460A, 460B, 460C and 460D may be arranged or disposed so that the ratio of the second light blocking patterns 454 and 474 with the second line width W2 different from the first line width W1 among the plurality of second area light blocking patterns 440, 440A, 440B, 460, 460A, 460B, 460C and 460D may gradually increase as the distance from the first area A1 (FIG. 9) of the black matrix pattern 400 to the edge 402 of the black matrix pattern 400 or the boundary area BA (FIG. 19) of the adjacent stamp area STP2 increases.

In one embodiment, all the plurality of first area light blocking patterns 410 disposed in the first area A1 of the black matrix pattern 400 may be the first light blocking patterns 420 enclosing each of the first openings 410 with the same first line width W1. All the black matrices 190 applying the first light blocking patterns 420 disposed in the first area A1 of the black matrix pattern 400 have identical arrangement position with respect to the light emitting diode E transferred to the display panel 120.

The ratio of the second light blocking patterns 452 and 472 enclosing each of the second openings 444 and 464 with the second line width W2 different from the first line width W1 increases toward the edge 402 of the black matrix pattern 400 or the boundary area BA of the adjacent stamp area STP2. The ratio of the black matrix 190 with different arrangement position with respect to the light emitting diode E transferred to the adjacent area of the display panel 120 is gradually shifted. The difference in luminance of light emitted from the light emitting diodes E transferred to the adjacent area of the display panel 120 hardly recognized.

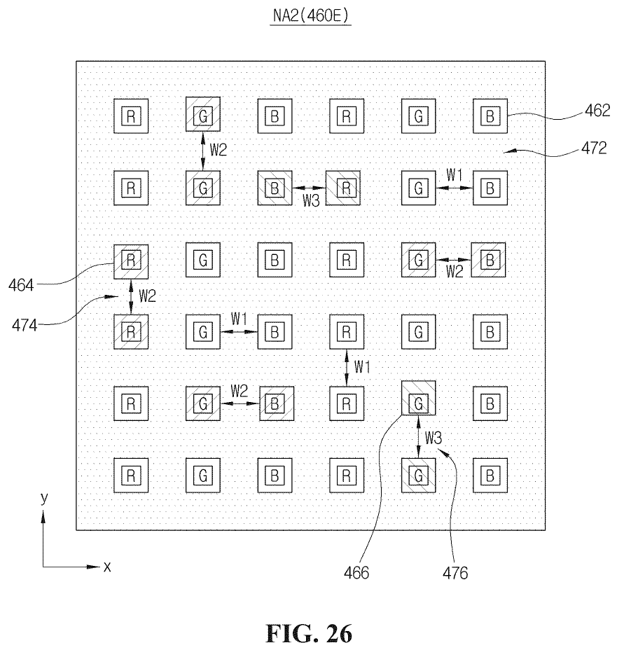

FIG. 26 illustrates a schematic arrangement of black matrix patterns in a second adjacent area in accordance with another embodiment of the present disclosure. The exemplary embodiment will be described referring to FIGS. 22, 25 and 26.

As illustrated in FIG. 26, the plurality of second adjacent area light blocking patterns 460E disposed or arranged in the second adjacent area NA2 of the black matrix pattern 400 comprise the plurality of first light blocking patterns 472 enclosing each of the first openings 462 with the first line width W1, the plurality of second light blocking patterns 474 enclosing each of the second openings 464 with the second line width W2, and the plurality of third light blocking patterns 476 enclosing each of the third openings 466 with the third line width W3. Compared to the arrangements of the second adjacent area light blocking patterns 440B, among the plurality of second adjacent area light blocking patterns 460E disposed in the second adjacent area NA2, the number of the plurality of second light blocking patterns 474 disposed with the second line width W2 and/or the number of the plurality of third light blocking patterns 476 disposed with the third line width W3 increase compared to the number of the plurality of first light blocking patterns 472 disposed with the first line width W1.

Referring to FIGS. 22 and 26, the ratio of the plurality of second light blocking patterns 454 with the second line width W2 different from the first line width W1 among the plurality of first adjacent area light blocking patterns 440B disposed in the first adjacent area NA1 differs from a ratio of the plurality of second light blocking patterns 474 and/or the plurality of third light blocking patterns 476 with the second line width W2 and/or the third line width W3 different from the first line width W1 among the plurality of second adjacent area light blocking patterns 470E.

The ratio of the second light blocking patterns 444 with the second line width W2 among the plurality of first adjacent area light blocking patterns disposed in the first adjacent area NA1 may be smaller than the ratio of the second light blocking patterns 474 and/or the third light blocking patterns 476 with the second line width W2 and/or the third line width W3 among the plurality of second adjacent area light blocking patterns 470E disposed in the second adjacent area NA2.

For example, the ratio of the second light blocking patterns 444 with the second line width W2 among the plurality of first adjacent area light blocking patterns 440B disposed in the first adjacent area NA1 may be about 1% to about 30%, for example, about 5% to about 25%, but is not limited thereto. As an example, the ratio of the second light blocking patterns 474 with the second line width W2 and/or the third light blocking patterns 476 with the third line width W3 among the plurality of second adjacent area light blocking patterns 470E disposed in the second adjacent area NA2 may be about 30% to 60%, for example, about 30% to about 50%, but is not limited thereto.

Compared to the arrangements of the second adjacent area light blocking patterns 470D in FIG. 25, the second adjacent area light blocking patterns 460E further comprises the plurality of third light blocking patterns 476 disposed with the third line width W3. The third line width W3 may be greater or smaller than the first line width W1 and/or the second line width W2. In one embodiment, the difference between the first line width W1 and the third line width W3 may be larger than the difference between the first line width W1 and the second line width W2.

The second line width W2 of the separation distance between the second openings 464 and/or the third line width W3 of the separation distance between the third openings 474 may be set identically or differently. The ranges of the second line width W2 and/or the ranges of the third line width W3 compared to the first line width W1, the second line width W2 and the third line width W3 set differently compared to the first line width W1 may be identical to the ranges and distances referring to FIGS. 21A and 21B.

In another embodiment, the plurality of second area light blocking patterns 440, 440A, 440B, 460, 460A, 460B, 460C and 460D may be arranged or disposed so that the ratio of the second light blocking patterns 454 and 474 and/or the third light blocking patterns 456 and 474 with the second line width W2 and/or the third line width W3 different from the first line width W1 among the plurality of second area light blocking patterns 440, 440A, 440B, 460, 460A, 460B, 460C and 460D may gradually increase as the distance from the first area A1 (FIG. 9) of the black matrix pattern 400 to the edge 402 of the black matrix pattern 400 or the boundary area BA (FIG. 19) of the adjacent stamp area STP2 increases.

The relative positions of the black matrix 190 (FIG. 3) with respect to the light emitting diode E (FIG. 3) transferred to the display panel 120 (FIG. 3) is gradually shifted as the distance from the first area A1 of the black matrix pattern 400 increases. The ratio of the second light blocking patterns 454 and 474 and/or the third light blocking patterns 456 and 476 with the second line width W2 and/or the third line width W3 different from the first line width W1 increases toward the edge 322 of the transfer head 320 or the boundary area BA of the adjacent stamp area STP2.

The ratio of the black matrix 190 having different alignment positions with respect to the light emitting diode E transferred to the adjacent area of the display panel gradually changed. With respect to the light emitting diode E transferred to the adjacent area of the display panel 120, the relative arrangement position difference among the black matrices 190 may be minimized or reduced, and therefore, the difference in luminance of light emitted from the light emitting diodes E transferred to the adjacent area of the display panel 120 is hardly recognized.

Table 2 below shows the arrangements of the plurality of black matrix patterns in which the line widths of the plurality of light blocking patterns enclosing each opening are differently set by the region of the whole black matrix patterns in accordance with exemplary embodiment of the present disclosure. In Table 2, arrangements of the black matrix patterns in the first stamp area STP1. In Table 2, the position represents the distance from the boundary area BA of the stamp areas STP1 and STP2, and X and Y shifts represents the relative separation distance among the opening enclosed by light blocking patterns shifted to have different line widths along the X and Y axes of the black matrix pattern, and the relative ratio of the light blocking patterns with different separation distance among the detachment components in the central area of the transfer head.

TABLE 2
Setting of Line Width in Black Matrix Patten

| Position (mm) | 10 | 9 | 8 | 7 | 6 | 5 | 4 | 3 | 2 | 1 |
|---|---|---|---|---|---|---|---|---|---|---|
| X, Y shift | 5% | 10% | 15% | 20% | 25% | 30% | 35% | 40% | 45% | 50% |
| ±0.2 μm | 2.5% | 3.5% | 5.0% | 6.5% | 8.0% | 9.5% | 11.0% | 12.5% | 14.0% | 15.5% |
| ±0.4 μm | 2.5% | 3.5% | 5.0% | 6.5% | 8.0% | 9.5% | 11.0% | 12.5% | 14.0% | 15.5% |
| ±0.6 μm | | 1.5% | 2.5% | 3.0% | 3.5% | 4.0% | 4.5% | 4.5% | 5.0% | 5.5% |
| ±0.8 μm | | 1.5% | 2.5% | 3.0% | 3.5% | 4.0% | 4.5% | 4.5% | 5.0% | 5.5% |
| ±1.0 μm | | | | 0.5% | 1.0% | 1.5% | 1.5% | 2.0% | 2.0% | 2.5% |
| ±1.2 μm | | | | 0.5% | 1.0% | 1.5% | 1.5% | 2.0% | 2.0% | 2.5% |
| ±1.4 μm | | | | | | | 0.5% | 1.0% | 1.0% | 1.0% |
| ±1.6 μm | | | | | | | 0.5% | 1.0% | 1.0% | 1.0% |
| ±1.8 μm | — | | | | | | | | 0.5% | 0.5% |
| ±2.0 μm | — | | | | | | | | 0.5% | 0.5% |

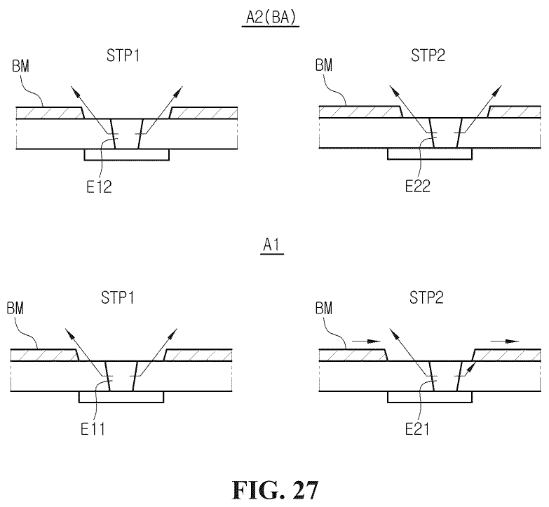

By arranging the plurality of light blocking patterns 410, 430, 450 and 470 with different line width by the area of the black matrix pattern 430, the stains in the boundary area of the stamp areas can be minimized or reduced. FIG. 27 illustrates a schematic diagram illustrating an alignment of the light emitting diode chip matches in the boundary area of stamp areas when the light emitting diode is transferred to the display panel using the black matrix pattern in accordance with one or more embodiments of the present disclosure.

Referring to FIG. 27, the relative arrangement locations of the black matrix BM with respect to the light emitting diodes E11 and E21 in the first area A1 within the first stamp area STP1 and the second stamp area STP2 may be different from each other.

According to the above embodiments and examples, all the first area light blocking patterns 410 disposed in the first area A1 of each of the stamp area STP1 and STP2 have the same first line width W1. On the contrary, the second area light blocking patterns 430, 440 and 460 disposed in the second area A2 each of the first stamp area STP1 and the second stamp area STP2 may include the first light blocking pattern with the first line width W1, and the second light blocking patterns and/or the third light blocking patterns with the second line width W2 and/or the third line width W3.

At least portions of black matrix BM disposed in the second area A2 of the second stamp area STP2 may have different line width from the black matrix BM disposed in the first area A1 of the stamp area STP2. Accordingly, the arrangement position of the black matrix BM with respect to the light emitting diode E12 in the second area A2 within the first stamp area STP1 may be matched with the arrangement position of the black matrix BM with respect to the light emitting diode E22 in the second area A2 within the second stamp area STP2.

Referring to FIGS. 18 and 27, in the area MA where the alignment positions of the black matrix BM respect to the light emitting diodes E12 and E22 match among the boundary area BA between the first stamp area STP1 and the second stamp area STP2, since the luminance of light emitted from the light emitting diode E12 disposed in the first stamp area STP1 is the same as the luminance of light emitted from the light emitting diode E22 disposed in the second stamp area STP2, the luminance difference is not recognized. In the area MA where the alignment positions of the black matrix BM respect to the light emitting diodes E12 and E22 match among the boundary area BA between the first stamp area STP1 and the second stamp area STP2, stamp stains due to the luminance difference do not occur. It is possible to implement a display device with improved image quality by minimizing or reducing stains due to the difference in luminance of light at the boundary area BA among the stamp areas STP1 to SPT6.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A stamp element for transferring a light emitting diode, the stamp element comprising:
a transfer head; and
a plurality of detachment components that protrude from a surface of the transfer head,
wherein the plurality of detachment components comprise:
a plurality of first detachment components disposed in a central area of the transfer head; and
a plurality of peripheral detachment components disposed in a peripheral area of the transfer head,
wherein the plurality of first detachment components are disposed with a first separation distance, and
wherein at least portions of the plurality of peripheral detachment components are disposed with a separation distance that is different from the first separation distance.

2. The stamp element of claim 1, wherein the at least portions of the plurality of peripheral detachment components comprise:
a plurality of second detachment components disposed with a second separation distance that is different from the first separation distance; and
a plurality of third detachment components disposed with a third separation distance that is different from the first separation distance and the second separation distance.

3. The stamp element of claim 2, wherein the second separation distance is greater than the first separation distance and the third separation distance is greater than the second separation distance.

4. The stamp element of claim 1, wherein the peripheral area of the transfer head comprises:
a first peripheral area between the central area of the transfer head and an edge of the transfer head; and
a second peripheral area between the first peripheral area of the transfer head and the edge of the transfer head.

5. The stamp element of claim 4, wherein at least portions of the plurality of peripheral detachment components disposed in the first peripheral area comprise a plurality of second detachment components disposed with a second separation distance that is different from the first separation distance, and
wherein at least portions of the plurality of peripheral detachment components disposed in the second peripheral area comprise a plurality of third detachment components disposed with a third separation distance that is different from the first separation distance and the second separation distance.

6. The stamp element of claim 5, wherein the second separation distance is greater than the first separation distance.

7. The stamp element of claim 5, wherein the third separation distance is greater than the second separation distance.

8. The stamp element of claim 5, wherein the at least portions of the plurality of peripheral detachment components disposed in the second peripheral area further comprise the plurality of second detachment components disposed with the second separation distance.

9. The stamp element of claim 5, wherein a difference between an average second separation distance among the plurality of second detachment components and the first separation distance differs from a difference between an average third separation distance among the plurality of third detachment components and the first separation distance.

10. The stamp element of claim 9, wherein the difference between the average second separation distance and the first separation distance is less than the difference between the average third separation distance and the first separation distance.

11. The stamp element of claim 4, wherein a ratio of peripheral detachment components with a separation distance different from the first separation distance among the plurality of peripheral detachment components disposed in the first peripheral area differs from a ratio of peripheral detachment components with a separation distance different from the first separation distance among the plurality of peripheral detachment components disposed in the second peripheral area.

12. The stamp element of claim 4, wherein a ratio of peripheral detachment components with a separation distance different from the first separation distance among the plurality of peripheral detachment components disposed in the first peripheral area is less than a ratio of peripheral detachment components with a separation distance different from the first separation distance among the plurality of peripheral detachment components disposed in the second peripheral area.

13. The stamp element of claim 4, wherein at least portions of the plurality of peripheral detachment components disposed in the first peripheral area and the second peripheral area comprise a plurality of second detachment components disposed with a second separation distance that is different from the first separation distance, and
wherein a ratio of the plurality of second detachment components with the second separation distance among the plurality of peripheral detachment components disposed in the first peripheral area differs from a ratio of second detachment components with the second separation distance among the plurality of peripheral detachment components disposed in the second peripheral area.

14. The stamp element of claim 13, wherein the ratio of the plurality of second detachment components with the second separation distance among the plurality of peripheral detachment components disposed in the first peripheral area is less than the ratio of the plurality of second detachment components with the second separation distance among the plurality of peripheral detachment components disposed in the second peripheral area.

15. The stamp element of claim 13, wherein the at least portions of the plurality of peripheral detachment components disposed in the second peripheral area further comprise a plurality of third detachment components disposed with a third separation distance that is different from the first separation distance and the second separation distance.

16. The stamp element of claim 1, wherein at least portions of the plurality of peripheral detachment components are disposed with a second separation distance that is different from the first separation distance, and
wherein a difference between the first separation distance and the second separation distance gradually increases or decreases as a distance from the central area of the transfer head increases.

17. The stamp element of claim 1, wherein a ratio of peripheral detachment components with a separation distance that is different from the first separation distance among the plurality of peripheral detachment components gradually increases as a distance from the central area of the transfer head increases.

18. A black matrix pattern for a display device, the black matrix pattern comprising:
a plurality of openings disposed correspondingly to each of emission areas of a display device; and
a plurality of light blocking patterns enclosing the plurality of openings, respectively, and disposed correspondingly to each of non-emission areas of the display device,
wherein the plurality of light blocking patterns comprise:
a plurality of first light blocking patterns that enclose the plurality of openings positioned in a first area, respectively; and
a plurality of second area light blocking patterns that enclose the plurality of openings positioned in a second area enclosing the first area, respectively,
wherein the plurality of first light blocking patterns are disposed with a first line width to each of the plurality of openings, and
wherein at least portions of the plurality of second area light blocking patterns are disposed with a line width different from the first line width.

19. The black matrix pattern of claim 18, wherein the at least portions of the plurality of second area light blocking patterns comprise:
a plurality of second light blocking patterns disposed with a second line width that is different from the first line width; and
a plurality of third light blocking patterns disposed with a third line width that is different from the first line width and the second line width.

20. The black matrix pattern of claim 19, wherein the second line width is greater than the first line width and the third line width is greater than the first line width.

21. The black matrix pattern of claim 18, wherein the second area comprises:
a first adjacent area enclosing the first area; and
a second adjacent area enclosing the first adjacent area.

22. The black matrix pattern of claim 21, wherein at least portions of the plurality of second area light blocking patterns disposed in the first adjacent area comprise a plurality of second light blocking patterns with a second line width that is different from the first line width, and
wherein at least portions of the plurality of second area light blocking patterns disposed in the second adjacent area comprise a plurality of third light blocking patterns with a third line width that is different from the first line width and the second line width.

23. The black matrix pattern of claim 22, wherein the second line width is greater than the first line width.

24. The black matrix pattern of claim 22, wherein the third line width is greater than the second line width.

25. The black matrix pattern of claim 22, wherein at least portions of the plurality of second area light blocking patterns disposed in the second adjacent area further comprise the plurality of second light blocking patterns with the second line width.

26. The black matrix pattern of claim 22, wherein a difference between an average second line width among the plurality of second light blocking patterns and the first line width differs from a difference between an average third line width among the plurality of third light blocking patterns and the first line width.

27. The black matrix pattern of claim 26, wherein the difference between the average second line width and the first line width is less than the difference between the average third line width and the first line width.

28. The black matrix pattern of claim 21, wherein a ratio of second area light blocking patterns with a line width different from the first line width among the plurality of second area light blocking patterns disposed in the first adjacent area differs from a ratio of second area light blocking patterns with a line width different from the first line width among the plurality of second area light blocking patterns disposed in the second adjacent area.

29. The black matrix pattern of claim 21, wherein a ratio of second area light blocking patterns with a line width different from the first line width among the plurality of second area light blocking patterns disposed in the first adjacent area is less than a ratio of second area light blocking patterns with a line width different from the first line width among the plurality of second area light blocking patterns disposed in the second adjacent area.

30. The black matrix pattern of claim 21, wherein at least portions of the plurality of second area light blocking patterns disposed in the first adjacent area and the second adjacent area comprise a plurality of second light blocking patterns disposed with a second line width different from the first line width, and
wherein a ratio of second light blocking patterns with the second line width among the plurality of second area light blocking patterns disposed in the first adjacent area differs from a ratio of second light blocking patterns with the second line width among the plurality of second area light blocking patterns disposed in the second adjacent area.

31. The black matrix pattern of claim 30, wherein the ratio of the second light blocking patterns with the second line width among the plurality of second area light blocking patterns disposed in the first adjacent area is less than the ratio of the second light blocking patterns with the second line width among the plurality of second area light blocking patterns disposed in the second adjacent area.

32. The black matrix pattern of claim 30, wherein the at least portions of the plurality of second area light blocking patterns disposed in the second adjacent area further comprise a plurality of third light blocking patterns disposed with a third line width that is different from the first line width and the second line width.

33. The black matrix pattern of claim 18, wherein at least portions of the plurality of second area light blocking patterns are disposed with a second line width that is different from the first line width, and
wherein a difference between the first line width and the second line width gradually increases or decreases as a distance from the first area increases.

34. The black matrix pattern of claim 18, wherein a ratio of second area light blocking patterns with a line width different from the first line width among the plurality of second area light blocking patterns gradually increases as a distance from the first area increases.
